(19) United States
(12) Patent Application Publication
(10) Pub. No.: US 2025/0293079 A1
(43) Pub. Date: Sep. 18, 2025

(54) AUTOMATED MECHANISM PLATFORM APPARATUS AND OPERATING METHOD THEREOF

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Lei GU, Shanghai City (CN); Lan ZHANG, Shanghai City (CN); Sheng Ying WANG, Shanghai City (CN); Liang CAI, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/620,908

(22) Filed: Mar. 28, 2024

(30) Foreign Application Priority Data
Mar. 14, 2024 (CN) 202420499808.8

(51) Int. Cl. H01L 21/687; H01L 21/67; H01L 21/677; H01L 21/68

(52) U.S. Cl. CPC H01L 21/68707; H01L 21/67075; H01L 21/67259; H01L 21/67769; H01L 21/68

(57) ABSTRACT

A method includes placing a first wafer carrier on a first wafer carrier support base of an automated mechanism platform apparatus, the first wafer carrier accommodating a plurality of wafers; grapping the wafers from the first wafer carrier by a gripper of the automated mechanism platform apparatus; moving the wafers from the gripper to a second wafer carrier placing on a second wafer carrier support base of the automated mechanism platform apparatus; grapping the second wafer carrier with the wafers from the second wafer carrier support base by the gripper; transferring the second wafer carrier with the wafers from the gripper to a processing apparatus.

### PRIORITY CLAIM AND CROSS-REFERENCE

The present application claims priority to China Application Serial Number 202420499808.8, filed Mar. 14, 2023, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a flowchart illustrating a method for semiconductor manufacturing in accordance with some embodiments of the present disclosure.

FIG. 1B is a flowchart illustrating a method of using an automation mechanism platform apparatus to automatically transfer wafers from a first wafer carrier to a second wafer carrier and move to a wet etch apparatus in accordance with some embodiments of the present disclosure.

FIGS. 2A-2E are cross-sectional views at various stages of manufacturing a semiconductor structure according to some embodiments of the present disclosure.

FIG. 3 illustrates a schematic perspective view of an automation mechanism platform apparatus with a wet etch apparatus in accordance with some embodiments of the present disclosure.

FIGS. 4A-4C illustrate schematic perspective views of an automation mechanism platform apparatus in accordance with some embodiments of the present disclosure.

FIG. 4D illustrates a schematic rear side view of an automation mechanism platform apparatus in accordance with some embodiments of the present disclosure.

FIG. 4E illustrates a schematic perspective view of a first wafer carrier support base of an automation mechanism platform apparatus for supporting a first wafer carrier on a first position of a carrying platform in accordance with some embodiments of the present disclosure.

FIG. 4F illustrates a schematic perspective view of a second wafer carrier support base of an automation mechanism platform apparatus for supporting a second wafer carrier on a second position of a carrying platform in accordance with some embodiments of the present disclosure.

FIG. 4G illustrates a schematic perspective view of a gripper of an automation mechanism platform apparatus for gripping wafers or a wafer carrier on a carrying platform in accordance with some embodiments of the present disclosure.

FIG. 4H illustrates a schematic top view of lifting modules of an automation mechanism platform apparatus for moving wafers or a wafer carrier in accordance with some embodiments of the present disclosure.

FIGS. 5-14C illustrates schematic views of various stages of a method for automatically transfer wafers from a first wafer carrier to a second wafer carrier and move to a wet etch apparatus by an automation mechanism platform apparatus in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

During the progression of integrated circuit (IC) development, certain apparatuses are employed to transfer wafers between various wafer carriers. Once the wafer has been shifted to an alternative carrier, this new carrier is then manually conveyed to the processing apparatus for the subsequent manufacturing process. After this manufacturing process is complete, the wafer carrier is once again manually relocated from the processing apparatus back to the transfer device to undergo another round of wafer carrier alteration. However, the manual transportation of wafer carriers can introduce human errors, potentially leading to damage or contamination of the wafers. In addition, Relying on manual processes can be less efficient and time-consuming. Furthermore, the constant need for manual intervention may increase labor costs in the long run.

Therefore, the present disclosure provides an automated mechanism platform apparatus to transfer wafers between diverse wafer carriers. Furthermore, this automated mechanism platform apparatus can be equipped to convey the wafer directly into the chamber of a processing apparatus, such as an acid trough apparatus. By these functionalities, the automated mechanism platform apparatus can boost the manufacturing efficiency of semiconductor structure. The automated mechanism platform apparatus can minimize human intervention, thus reducing the potential for human-induced errors, mishandling, or contamination. Automated systems maintain a consistent and controlled environment, ensuring wafers are handled with precision, reducing the chances of physical damage. Moreover, by eliminating manual transfers, the automated mechanism platform apparatus can decrease the exposure of wafers to contaminants, ensuring their integrity throughout the process. Operating on electric control, the automated mechanism platform apparatus can offer visualized operational data, encapsulates a modular approach to its diverse functions, and boasts a streamlined design.

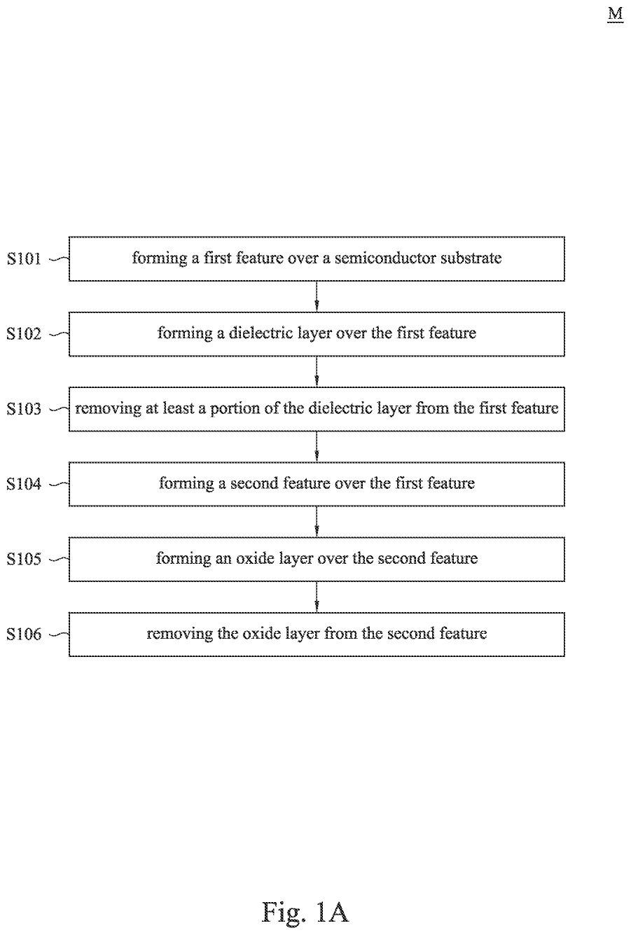

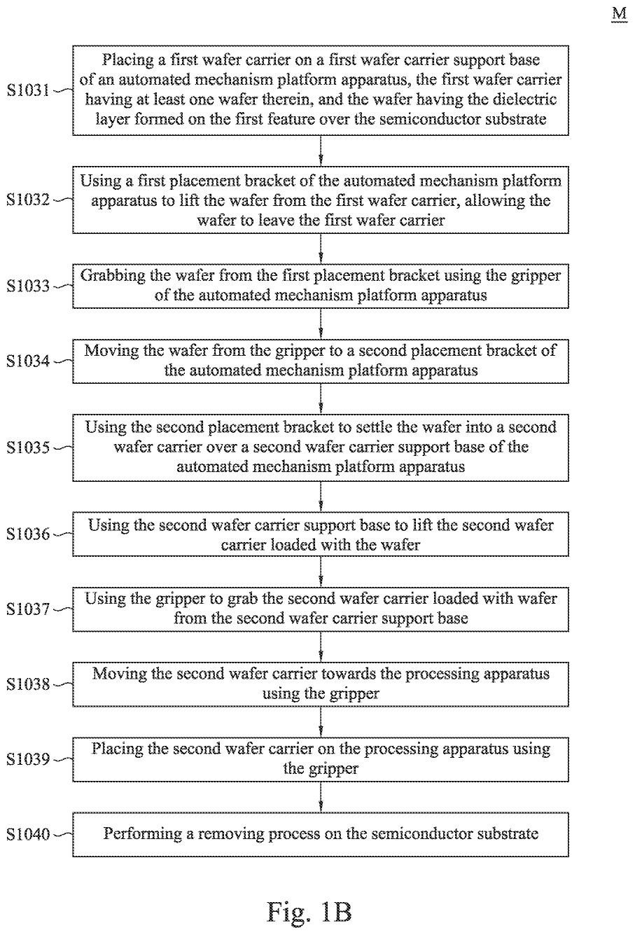

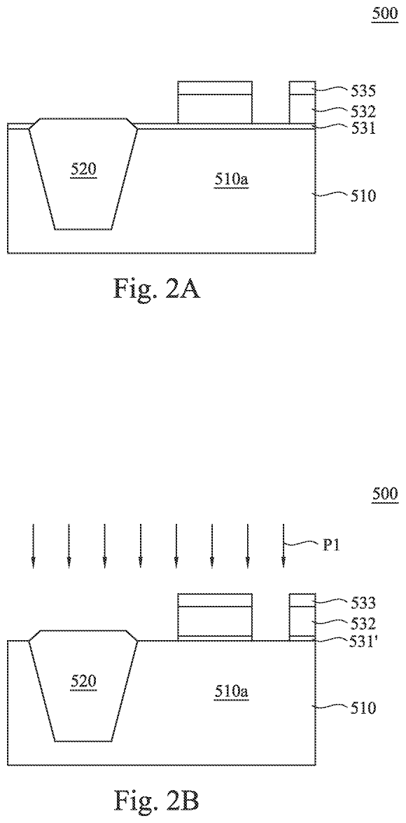

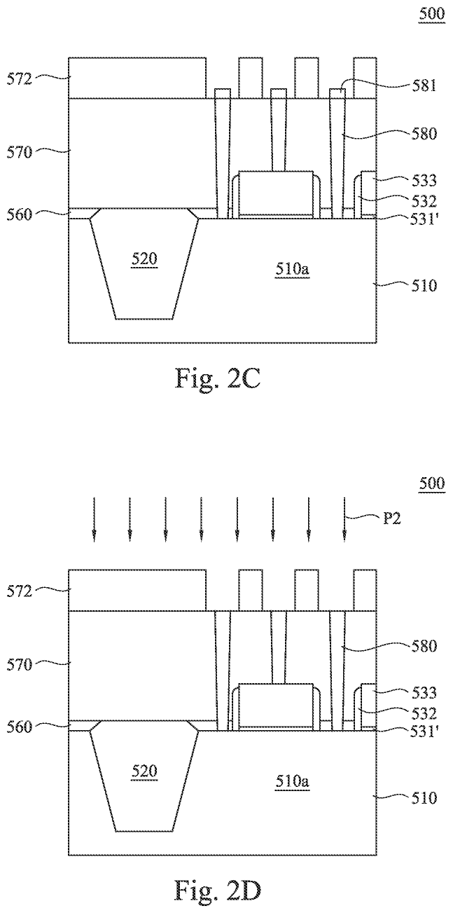

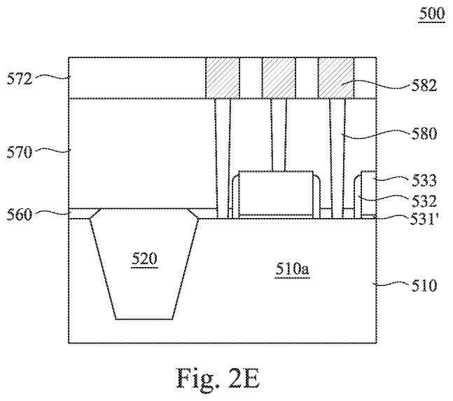

Reference is made to FIGS. 1A-14C. FIG. 1A is a flowchart illustrating a method M for semiconductor manufacturing with reference to FIGS. 2A-2D in accordance with some embodiments of the present disclosure. FIGS. 2A-2E are cross-sectional views at various stages of manufacturing the semiconductor structure 500 according to some embodiments of the present disclosure. The method M includes a relevant part of the semiconductor manufacturing process.

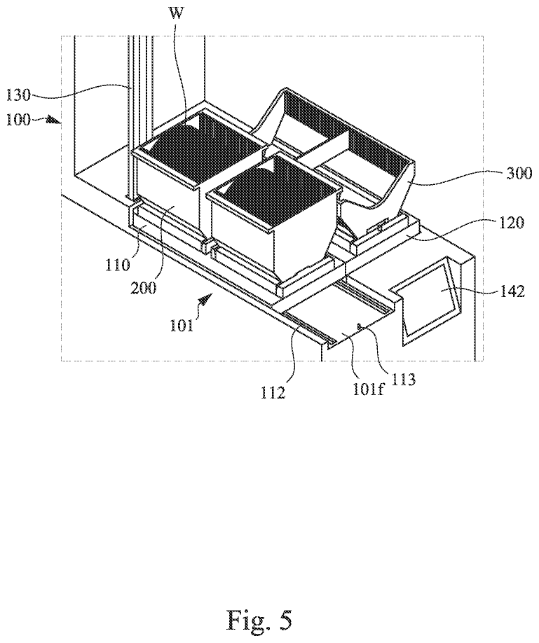

FIG. 1B is a flowchart further illustrating the method M of using the automation mechanism platform apparatus 100 to automatically transfer wafers W between different wafer carriers 200 and 300 and move the wafer W with the new wafer carrier (e.g., wafer carrier 300) to a processing apparatus 400 (e.g., wet etch apparatus) to conduct a removing process P1, with reference to FIGS. 5-14C, in accordance with some embodiments of the present disclosure. FIGS. 5-14C illustrates schematic views of various stages of a method for automatically transfer wafers between different wafer carriers (e.g., wafer carriers 200 and 300) and move the wafer W with the new wafer carrier (e.g., wafer carrier 300) by the automation mechanism platform apparatus 100 in accordance with some embodiments of the present disclosure. It is understood that additional operations may be provided before, during, and after the operations shown by FIGS. 2A-2E and 5-14C, and some of the operations described below can be replaced or eliminated for additional embodiments of the method. The order of the operations/processes may be interchangeable.

Referring back to FIG. 1A, the method M then proceeds to block S101 where a first feature (e.g., an active region) is formed over a semiconductor substrate. With reference to FIG. 2A, in some embodiments of block S101, a semiconductor substrate 510 is provided. An isolation structure 520 is formed over the semiconductor substrate 510 for defining active regions 510a. In some embodiments, the semiconductor substrate 510 may include suitable semiconductor material, such as silicon. Formation of the isolation structure 520 may include patterning the semiconductor substrate 500 to form one or more trenches in the semiconductor substrate 500 by using suitable photolithography and etching techniques, depositing one or more dielectric materials (e.g., silicon oxide) to completely fill the trenches in the semiconductor substrate 500, followed by a planarization process (e.g., chemical mechanical polish (CMP) process) to level the isolation structure 520 with the active region 510a.

In some embodiments, the isolation structure 520 may include one or more suitable dielectric materials, such as silicon oxide, silicon nitride, silicon oxynitride, the like, or the combination thereof. The dielectric materials of the isolation structure 520 may be deposited using a high density plasma chemical vapor deposition (HDP-CVD), a low-pressure CVD (LPCVD), sub-atmospheric CVD (SACVD), a flowable CVD (FCVD), spin-on coating, and/or the like, or a combination thereof. After the deposition, an anneal process or a curing process may be performed, especially when the isolation structure 520 is formed using flowable CVD. In some embodiments, the isolation structure 520 may have a top surface higher than a top surface of the active region 510a. In some embodiments, the isolation structure 520 may have the top surface substantially level with a top surface of the active region 510a. In some embodiments, the isolation structure 520 can be further recessed (e.g., by an etch back process) to fall below the top surfaces of the active region 510a, such that the active region 510a can protrude above the top surface of the recessed isolation structure 520 to form fin-like structures, which in turn allows for forming fin-type field effect transistors (FinFETs) over the active region 510a.

Referring back to FIG. 1A, the method M then proceeds to block S102 where a dielectric layer (e.g., a gate dielectric layer) is formed over the first feature (e.g., the active region). With reference to FIG. 2A, in some embodiments of block S102, a gate stack 530 can be formed over the active region 510a. The gate stack 530 may include a gate dielectric layer 531, a gate electrode 532 over the gate dielectric layer 531, and a hard mask 533 over the gate electrode 532. In some embodiments, the gate dielectric layer 531 may include suitable dielectric materials, such as silicon oxide, the like, or the combination thereof. In some embodiments, gate dielectric layer 531 may include high-k gate dielectric materials including, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), metal oxides, metal nitrides, metal silicates, transition metal-oxides, transition metal-nitrides, transition metal-silicates, oxynitrides of metals, metal aluminates, zirconium silicate, zirconium aluminate, zirconium oxide, titanium oxide, aluminum oxide, hafnium dioxide-alumina (HfO₂—Al₂O₃) alloy, other suitable high-k dielectric materials, and/or combinations thereof.

In some embodiments, the gate electrode 532 may include polysilicon. In some embodiments, the gate electrode 532 can be a single layer structure or a multi-layer structure including, for example, copper (Cu), aluminum (Al), titanium (Ti), titanium nitride (TiN), tantalum (Ta), tantalum nitride (TaN), tantalum carbide (TaC), tantalum silicon nitride (TaSiN), tungsten (W), tungsten nitride (WN), molybdenum nitride (MoN), the like and/or combinations thereof. In some embodiments, the hard mask 533 may include suitable hard mask materials, such as silicon nitride.

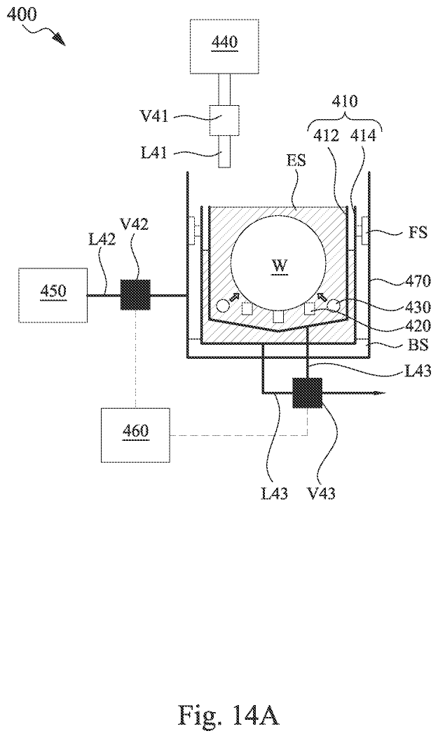

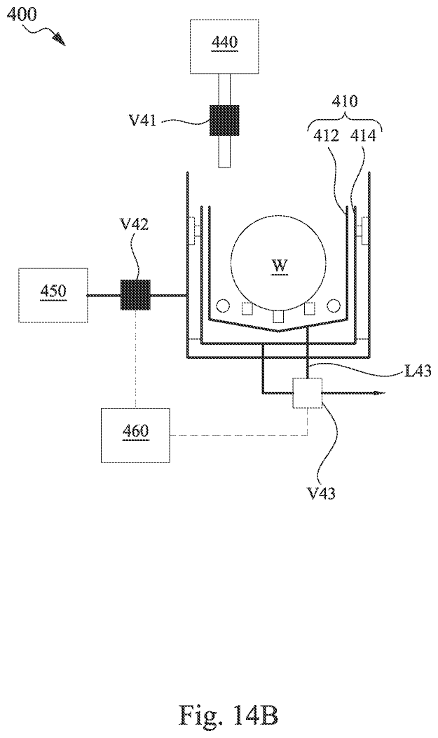

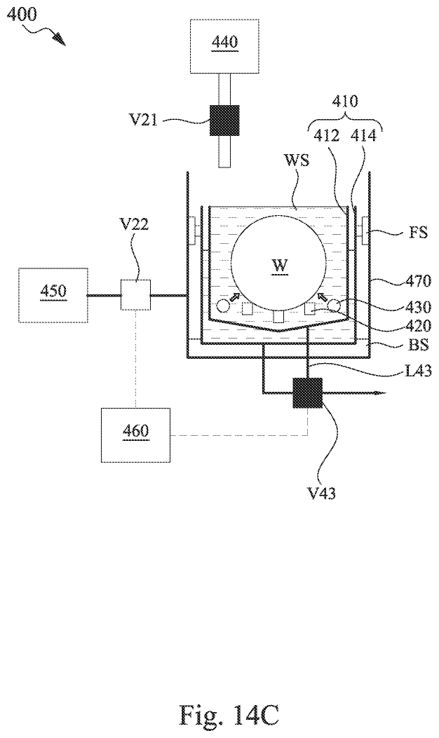

Referring back to FIG. 1A, the method M then proceeds to block S103 where at least a portion of the dielectric layer (e.g., the gate dielectric layer) is removed from the first feature (e.g., the active region). With reference to FIG. 2B, in some embodiments of block S103, the gate dielectric layer 531 (see FIG. 2A) is patterned into a gate dielectric 531′ by the removing process P1, such as a wet etch process, by using the hard mask 533 as an etch mask. The removing process P1 can be performed in a process chamber 410 (see FIGS. 14A-14C) of the processing apparatus 400. By the wet etch process, portions of the gate dielectric layer 531 (see to FIG. 2A) uncovered by the hard mask 533 are removed, and a portion of the gate dielectric layer 531 (see FIG. 2A) below the hard mask 533 remains and forms the gate dielectric 531′. In some embodiments, the process chamber 410 can also interchangeably be referred to as a process bath.

During the removing process P1, the wafer W, along with its wafer carrier, is placed inside the process chamber 410. If the wafer carrier, which is used for transporting wafer W between apparatuses, is inserted into the process chamber 410, it might damage the wafer carrier and potentially contaminate the wafer W. Therefore, this disclosure employs the automation mechanism platform apparatus 100 to transfer the wafer W to a wafer carrier that can withstand the removing process P1 before placing it into the process chamber 410. This ensures that the wafer carrier is not damaged and the wafer W remains uncontaminated. The automation mechanism platform apparatus 100 can serve to efficiently transfer the wafers W between wafer carriers, ensuring they are placed in suitable wafer carriers that can withstand specific processes, such as the removing process P1. The automation mechanism platform apparatus 100 can aim to prevent potential damage to the carriers and contamination of the wafers W, enhancing the overall efficiency and safety of wafer processing.

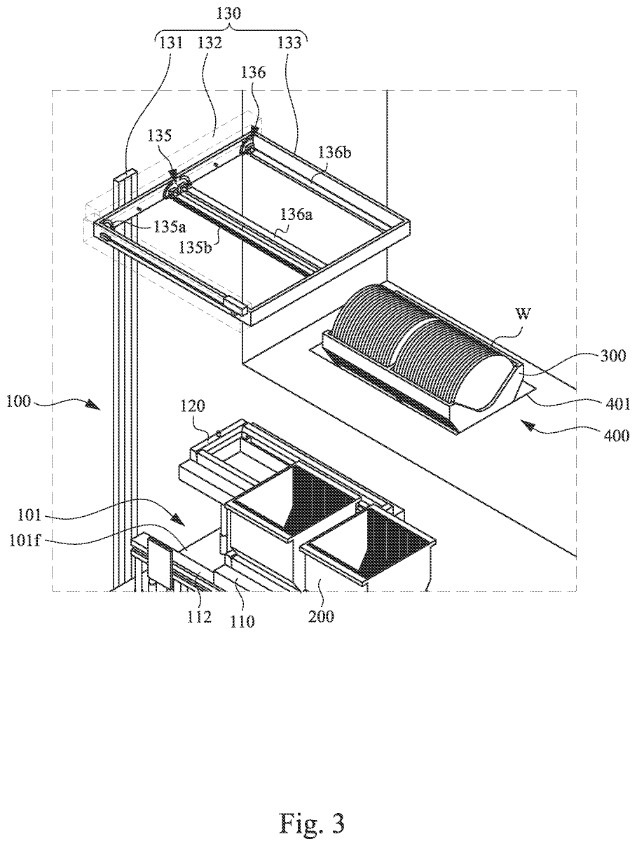

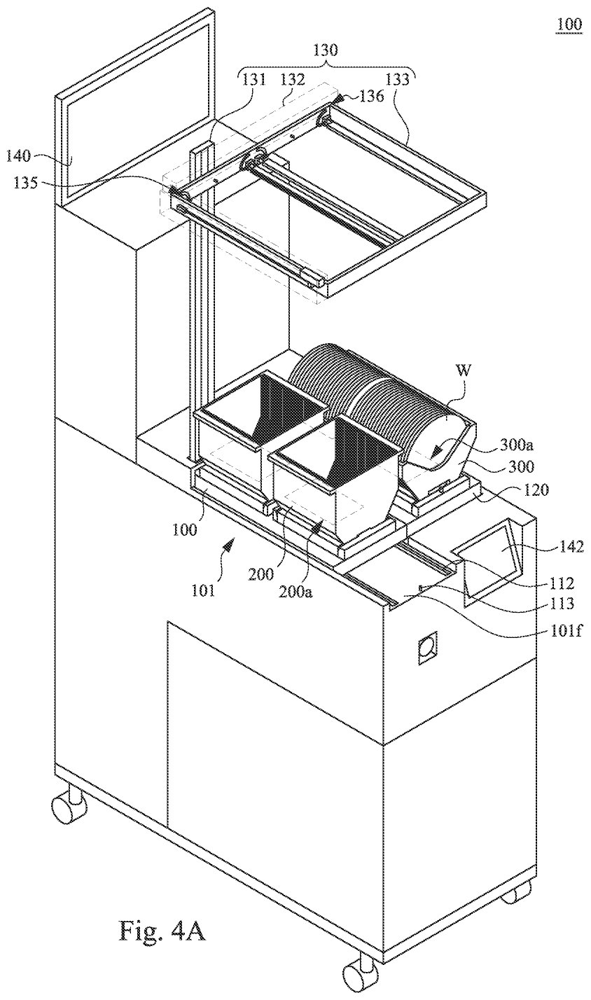

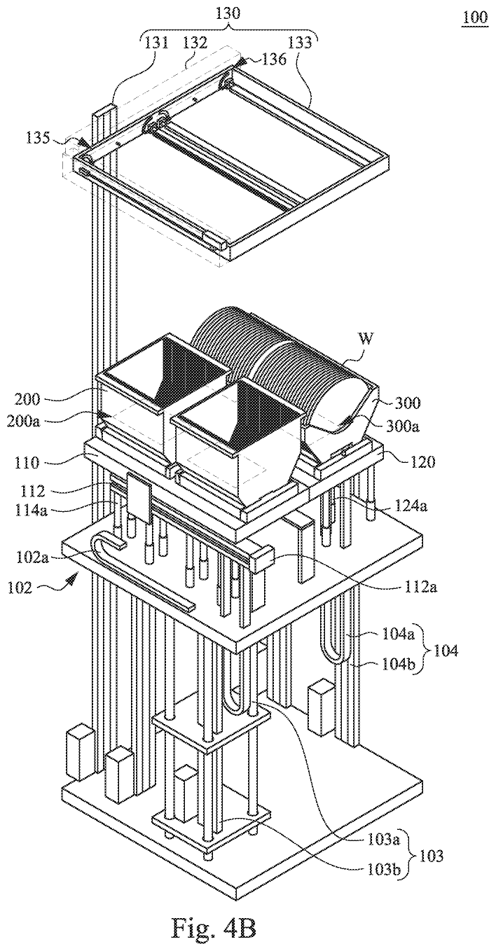

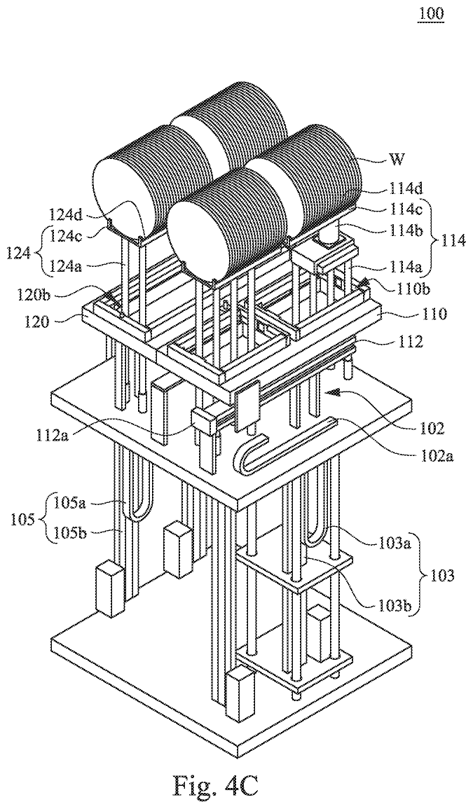

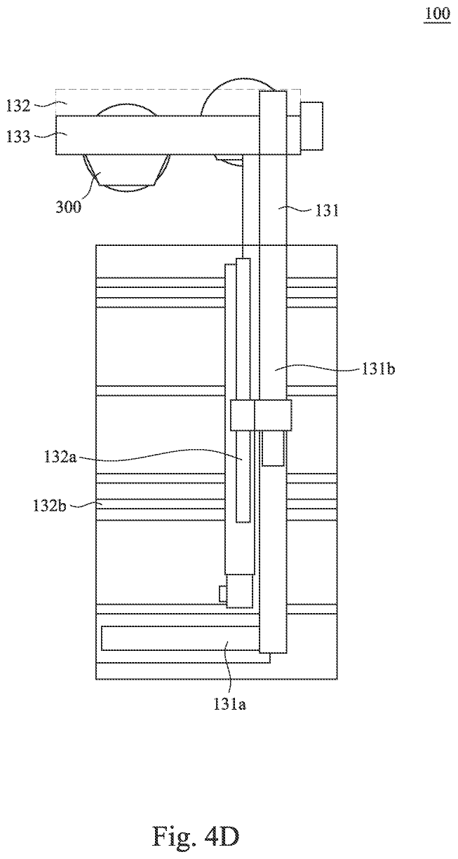

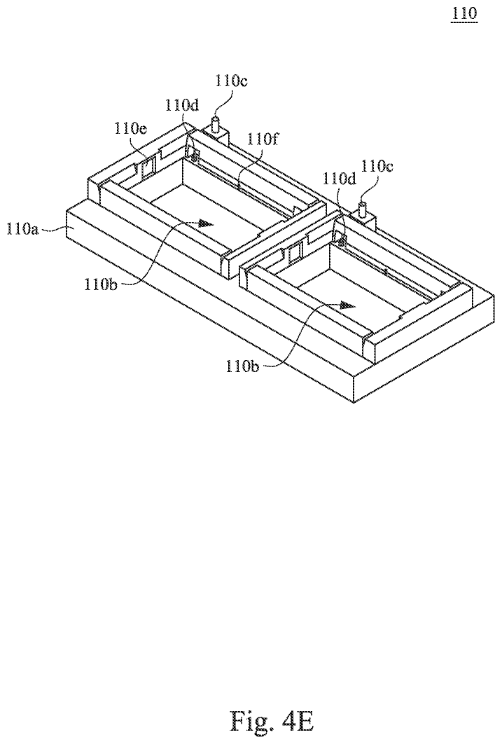

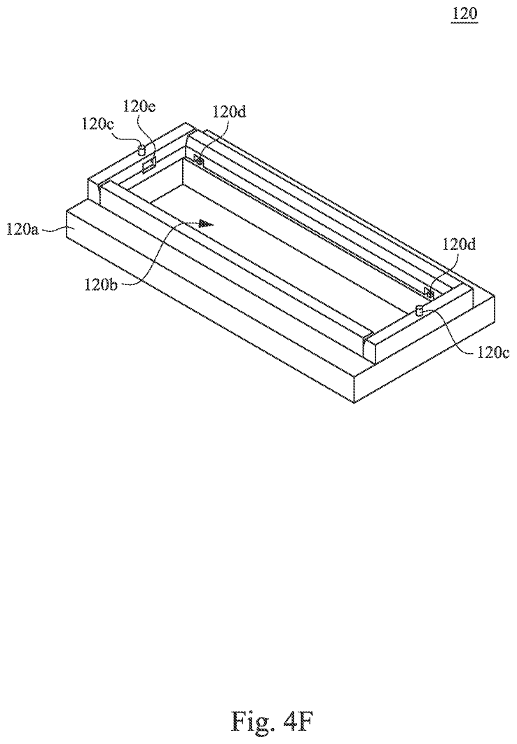

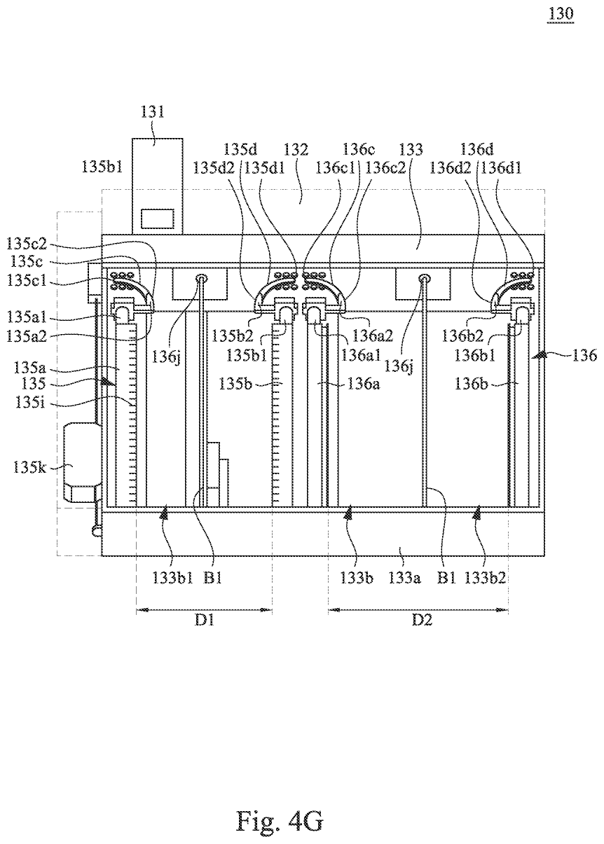

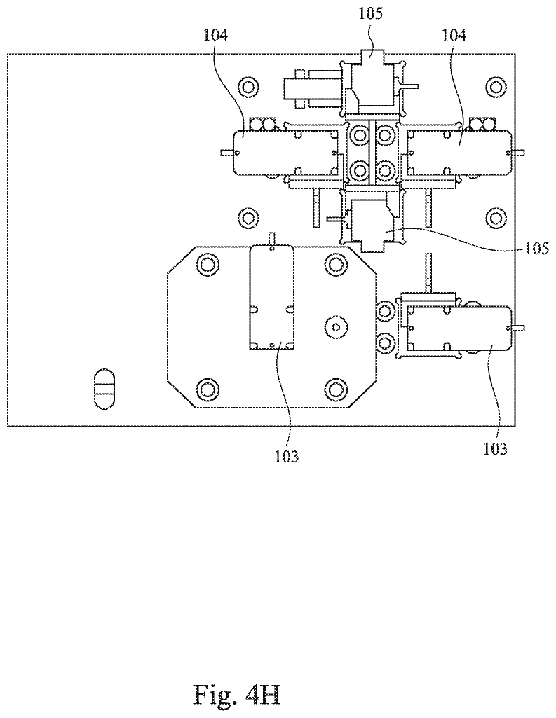

The automated mechanism platform apparatus 100 can transfer wafers W between different wafer carriers (e.g., wafer carriers 200 and 300). Furthermore, the automated mechanism platform apparatus 100 can be equipped to convey the wafer W directly into the process chamber 410 of the processing apparatus 400, such as an acid trough apparatus. By these functionalities, the automated mechanism platform apparatus 100 can boost the manufacturing efficiency of semiconductor structure. The automated mechanism platform apparatus can minimize human intervention, thus reducing the potential for human-induced errors, mishandling, or contamination. Automated systems maintain a consistent and controlled environment, ensuring wafers W are handled with precision, reducing the chances of physical damage. Moreover, by eliminating manual transfers, the automated mechanism platform apparatus 100 can decrease the exposure of wafers W to contaminants, ensuring their integrity throughout the process. Operating on electric control, the automated mechanism platform apparatus 100 can offer visualized operational data, encapsulates a modular approach to its diverse functions, and boasts a streamlined design. The detailed structure of the automation mechanism platform apparatus 100 is illustrated in FIGS. 3-4H.

Reference is made to FIGS. 3-4H. FIG. 3 illustrates a schematic perspective view of the automation mechanism platform apparatus 100 with the processing apparatus 400 (e.g., a wet etch apparatus) in accordance with some embodiments of the present disclosure. FIGS. 4A-4D illustrate schematic views of the automation mechanism platform apparatus 100 in accordance with some embodiments of the present disclosure, in which parts of the automation mechanism platform apparatus 100 in FIGS. 4A and 4B are omitted for the purpose of clarity. FIGS. 4E and 4F illustrate a schematic perspective view of first and second wafer carrier support base 110 and 120 of the automation mechanism platform apparatus 100 for supporting the first and second wafer carriers 200 and 300 on first and second positions of a carrying platform 101 in accordance with some embodiments of the present disclosure. FIG. 4G illustrates a schematic perspective view of a gripper 130 of an automation mechanism platform apparatus for gripping wafers or a wafer carrier on a carrying platform in accordance with some embodiments of the present disclosure. FIG. 4H illustrates a schematic top view of lifting module 103, 104, and 105 of the automation mechanism platform apparatus 100 for moving the wafers W or the wafer carrier 300 in accordance with some embodiments of the present disclosure.

The automated mechanism platform apparatus 100 can include a carrying platform 101 (see FIGS. 3 and 4A) and a gripper 130 (see FIGS. 3-4B) located on the carrying platform 101. On a first side of a carrying surface 101f (see FIGS. 3 and 4A) of the carrying platform 101, there is a horizontal movement guide rail 112 (see FIGS. 3-4B), and on the horizontal movement guide rail 112, there is the first wafer carrier support base 110. On a second side of the carrying surface 101f of the carrying platform 101, there is the second wafer carrier support base 120. The first wafer carrier support base 110 is used to carry the first wafer carrier 200 (see FIGS. 3-4B), while the second wafer carrier support base 120 is used to carry the second wafer carrier 300 (see FIGS. 3-4B).

In some embodiments, the first wafer carrier support base 110 (see FIGS. 3-4B and 4E) can carry multiple first wafer carriers 200 (e.g., two). Specifically, the first wafer carrier support base 110 includes a frame 110a (see FIG. 4E), which is a square frame structure and has multiple (e.g., two) square openings 110b (see FIG. 4E), respectively used to accommodate multiple (e.g., two) first wafer carriers 200. The openings 110b are arranged in an extension direction of the horizontal movement guide rail 112. The second wafer carrier support base 120 (see FIGS. 3-4B and 4F) includes a frame 120a (see FIG. 4F), which is a square frame structure and has a square opening 120b (see FIG. 4F), used to accommodate the second wafer carrier 300. In some embodiments, the first wafer carrier support base 110 and/or the second wafer carrier support base 120 can also interchangeably be referred to as a wafer carrier (or cassette) unloading base or a crystal boat unloading base. The frame 110a of the first wafer carrier support base 110 also has an anti-misplacement column 110f (see FIG. 4E) to position the first wafer carrier 200 on the frame 110a when it is accommodated. In some embodiments, the first wafer carrier 200 is made of quartz and/or polypropylene (PP), while the second wafer carrier 300 is made of a material that can resist the acid in the process chamber 410 of the processing apparatus 400 (e.g., Teflon). In some embodiments, the first wafer carrier 200 is made of n non-Teflon material. In some embodiments, the first wafer carrier 200 is made of a different material than the second wafer carrier 300. In some embodiments, the first wafer carrier 200 (see FIGS. 3-4B) and/or the second wafer carrier 300 (see FIGS. 3-4B) can also be interchangeably referred to as a crystal boat.

The automated mechanism platform apparatus 100 includes a horizontal movement module 102 (see FIGS. 4B and 4C). A silent drag chain 102a (see FIGS. 4B and 4C) included in the horizontal movement module 102 can drive the horizontal movement guide rail 112, allowing the first wafer carrier support base 110 (see FIGS. 4B and 4C) to move in the extension direction of the horizontal movement guide rail 112 (see FIGS. 4B and 4C). The horizontal movement guide rail 112 has a movement limit element 112a (see FIGS. 4B and 4C), used to physically restrict the movement range of the first wafer carrier 200 (see FIG. 4B) on the horizontal movement guide rail 112 (see FIGS. 4B and 4C), ensuring that the first wafer carrier 200 can move on the horizontal movement guide rail 112.

In some embodiments, the carrying platform 101 can have a safety light curtain 113 (see FIG. 4A) thereon. The safety light curtain 113 can be located on the carrying surface 101f (see FIG. 4A) of the carrying platform 101 (see FIG. 4A) and is positioned between the two rails (tracks) of the horizontal movement guide rail 112 (see FIG. 4A). The safety light curtain 113 has optical transmitting elements and optical receiving elements, used to detect whether other objects are within the actuation range of the horizontal movement guide rail 112, ensuring the normal operation of the horizontal movement guide rail 112 and the safety of the staff.

In some embodiments, the first wafer carrier support base 110 (see FIG. 4E) also includes a wafer carrier reading detection device 110c (see FIG. 4E), a wafer carrier positioning detection device 110d (see FIG. 4E), and a wafer sensing device 110e (see FIG. 4E). The wafer carrier reading detection device 110c can be used to detect whether the first wafer carrier 200 is positioned above the opening 110b of the corresponding first wafer carrier support base 110. The wafer carrier positioning detection device 110d can be used to determine if the first wafer carrier 200 is housed within the opening 110b of the corresponding first wafer carrier support base 110, ensuring the correct placement of the first wafer carrier 200 within the opening 110b of the first wafer carrier support base 110. Specifically, the wafer carrier positioning detection device 110d is designed to accurately sense the positioning of the first wafer carrier 200. Using a combination of sensors, it can determine whether the first wafer carrier 200 is correctly aligned and seated within the opening 110b. When the first wafer carrier 200 is positioned accurately, it ensures that the wafer W can be safely and accurately moved to and from it. On the contrary, if the first wafer carrier 200 is placed misaligned, it poses risks in subsequent wafer handling steps. For example, an improper placement can lead to physical damage to the wafer W, especially during automated movements or subsequent processing steps. If the wafer carrier positioning detection device 110d identifies that the first wafer carrier 200 is misaligned, the automated mechanism platform apparatus 100 can halt subsequent processes, alerting operators or technicians to rectify the situation. This preventive measure ensures the safety of the wafers W and the efficiency of the entire process. The wafer sensing device 110e can be used to sense whether there are wafers W loaded in the first wafer carrier 200.

In some embodiments, the wafer carrier reading detection device 110c, the wafer carrier positioning detection device 110d, and/or wafer sensing device 110e can be either a diffuse-reflective sensor or a thrubeam sensor. The diffuse-reflective sensor employs a unified design containing both a corresponding transmitter and a corresponding receiver within a single housing. This type of sensor functions by emitting a light beam, usually infrared, towards the target (e.g., the first wafer carrier 200 or the wafer W). When the emitted beam strikes the first wafer carrier 200 or the wafer W, it is scattered in various directions. A portion of this scattered or diffused light is reflected back to the sensor where it is received and detected. In addition, the thrubeam sensor operates using two separate components: a transmitter mounted on a first sidewall of the opening 110b, and a receiver mounted on a second sidewall of the opening 110b opposite to the first sidewall.

In some embodiments, the second wafer carrier support base 120 (see FIG. 4F) can also include a wafer carrier reading detection device 120c (see FIG. 4F), a wafer carrier positioning detection device 120d (see FIG. 4F), and a wafer sensing device 120e (see FIG. 4F). The wafer carrier reading detection device 120c can be used to detect whether the second wafer carrier 300 is located above the opening 120b of the second wafer carrier support base 120. The wafer carrier positioning detection device 120d can be used to determine if the second wafer carrier 300 is accommodated within the opening 120b of the second wafer carrier support base 120, ensuring the correct placement of the second wafer carrier 300 within the opening 120b of the second wafer carrier support base 120. Specifically, the wafer carrier positioning detection device 120d is designed to accurately sense the positioning of the second wafer carrier 300. Using a combination of sensors, it can determine whether the second wafer carrier 300 is correctly aligned and seated within the opening 120b. When the second wafer carrier 300 is positioned accurately, it ensures that the wafer can be safely and accurately moved to and from it. On the contrary, if the second wafer carrier 300 is placed misaligned, it poses risks in subsequent wafer handling steps. For example, an improper placement can lead to physical damage to the wafer W, especially during automated movements or subsequent processing steps. If the wafer carrier positioning detection device 120d identifies that the second wafer carrier 300 is misaligned, the automated mechanism platform apparatus 100 can halt subsequent processes, alerting operators or technicians to rectify the situation. This preventive measure ensures the safety of the wafers W and the efficiency of the entire process. The wafer sensing device 120e can be used to sense whether wafers W are loaded in the second wafer carrier 300. In some embodiments, the wafer carrier reading detection device 120c, wafer carrier positioning detection device 120d, and/or wafer sensing device 120e can be either a diffuse-reflective sensor or a thrubeam sensor.

The automated mechanism platform apparatus 100 has at least one first placement bracket 114 (see FIG. 4C), which is movably set on the carrying platform 101 (see FIG. 4C) and is located at the opening 110b (see FIGS. 4C and 4E) of the first wafer carrier support base 110 (see FIGS. 4C and 4E). When the first wafer carrier 200 is placed on the first wafer carrier support base 110, the side of the first wafer carrier 200 facing the first wafer carrier support base 110 has an opening that exposes the wafer W. The first placement bracket 114 can vertically lift the wafer W (see FIG. 4C) in the first wafer carrier 200 through the opening facing the first wafer carrier support base 110, while leaving the first wafer carrier 200 (see FIG. 4B) on the horizontal movement guide rail 112 (see FIGS. 4B and 4C). Alternatively, the first placement bracket 114 (see FIG. 4C) can vertically settle the wafer W into the wafer carrier 200 (see FIG. 4B). In some embodiments, the first placement bracket 114 can be interchangeably referred to as a wafer lifting device.

In detail, the first placement bracket 114 (see FIG. 4C) includes multiple brackets 114a (see FIG. 4C), a rotor 114b (see FIG. 4C) on bracket 114a, and a placement platform 114c (see FIG. 4C) supported on the rotor 114b. The placement platform 114c of the first placement bracket 114 contacts and pushes/supports the wafer W (see FIG. 4C) through the opening 200a (see FIGS. 4A and 4B) in the first wafer carrier 200 facing the first wafer carrier support base 110. The placement platform 114c of the first placement bracket 114 has a plurality of slots 114d (see FIG. 4C), which is arranged along the extension direction of the horizontal movement guide rail 112, to vertically position the wafer W over the placement platform 114c. The automated mechanism platform apparatus 100 includes a lifting module 103 (see FIGS. 4C and 4H), which includes of a silent drag chain 103a (see FIG. 4C) and an electric cylinder lifting mechanism 103b (see FIG. 4C). The electric cylinder lifting mechanism 103b of the lifting module 103 can drive the silent drag chain 103a to vertically lift or lower the bracket 114a, causing the bracket 114a to drive the placement platform 114c to move vertically. The rotor 114b of the first placement bracket 114 can rotate the placement platform 114c to change the orientation of the wafer W relative to the first wafer carrier support base 110. In some embodiments, the rotor 114b is a rotating micro motor.

The automated mechanism platform apparatus 100 has a second placement bracket 124 (see FIG. 4C), which is movably set on the carrying platform 101 (see FIG. 4C) and is located at the opening 120b (see FIGS. 4C and 4F) of the second wafer carrier support base 120 (see FIGS. 4C and 4F). When the second wafer carrier 300 is placed on the second wafer carrier support base 120, one side of the second wafer carrier 300 facing the second wafer carrier support base 120 has an opening 300a (see FIGS. 4A and 4B). The second placement bracket 124 can vertically settle the wafer W (see FIGS. 4B and 4C) from a lifting gripper platform 133 (see FIG. 4B) into the second wafer carrier 300 (see FIG. 4B) through the opening 300a of the second wafer carrier 300 facing the second wafer carrier support base 120. Alternatively, the second placement bracket 124 can vertically lift the wafer W in the second wafer carrier 300, while leaving the second wafer carrier 300 on the second wafer carrier support base 120. In some embodiments, the second placement bracket 124 can also be interchangeably referred to as a wafer lifting device.

In detail, the second placement bracket 124 (see FIG. 4C) includes multiple brackets 124a (see FIG. 4C) and a placement platform 124c (see FIG. 4C) supported on bracket 124a. The placement platform 124c of the second placement bracket 124 contacts and supports/pushes the wafer W (see FIG. 4C) through the opening 300a (see FIGS. 4A and 4B) in the second wafer carrier 300 facing the second wafer carrier support base 120. The placement platform 124c of the second placement bracket 124 has a plurality of slots 124d (see FIG. 4C), which is arranged along the extension direction of the horizontal movement guide rail 112, to vertically position the wafer W over the placement platform 124c. The automated mechanism platform apparatus 100 includes a lifting module 104 (see FIGS. 4C and 4H), which includes of a silent drag chain 104a (see FIG. 4C) and an electric cylinder lifting mechanism 104b (see FIG. 4C). The electric cylinder lifting mechanism 104b of the lifting module 104 can drive the silent drag chain 104a to vertically lift or lower the bracket 124a, causing the bracket 124a to drive the placement platform 124c to move vertically.

The automated mechanism platform apparatus 100 includes a lifting module 105 (see FIGS. 4C and 4H), which includes of a silent drag chain 105a (see FIG. 4C) and an electric cylinder lifting mechanism 105b (see FIG. 4C). The electric cylinder lifting mechanism 105b of the lifting module 104 can drive the silent drag chain 105a to vertically lift or lower the second wafer carrier support base 120.

The gripper 130 (see FIGS. 3, 4A, 4B, 4D, and 4G) may include of a lifter 131 mounted on the carrying platform 101, a horizontal movement guide rail 132 placed on the lifter 131, and a lifting gripper platform 133 set on the horizontal movement guide rail 132. The lifter 131 drives a gear rack 131b (see FIG. 4D) to move the lifting gripper platform 133 vertically through a drag chain 131a (see FIG. 4D), while the horizontal movement guide rail 132 drives a gear rack 132b (see FIG. 4D) to move the lifting gripper platform 133 horizontally through a drag chain 132a (see FIG. 4D). In some embodiments, an extension direction of the horizontal movement guide rail 132 is perpendicular to the extension direction of the horizontal movement guide rail 112 placed on the first side of the carrying platform 101.

The lifting gripper platform 133 (see FIG. 4G) includes a frame 133a (see FIG. 4G), a clamping structure 135 (see FIG. 4G), and a clamping structure 136 (see FIG. 4G). In some embodiments, the frame 133a is a square frame structure and has a square opening 133b (see FIG. 4G). A first side 133b1 (see FIG. 4G) of the opening 133b can be used to accommodate the wafer W, and a second side 133b2 (see FIG. 4G) of the opening 133b can be used to accommodate the second wafer carrier 300. The clamping structure 135 is set on the first side 133b1 of the opening 133b of the frame 133a, and the clamping structure 136 is set on the second side 133b2 of the opening 133b of the frame 133a. Both clamping structures 135 and 136 are arranged along the extension direction of the horizontal movement guide rail 132. The clamping structure 135 is used to grip the wafer W, while the clamping structure 136 is used to grip the second wafer carrier 300.

In detail, the clamping structure 135 (see FIG. 4G) has a clamping portion 135a (see FIG. 4G), a clamping portion 135b (see FIG. 4G), two rotation limiting mechanisms 135c (see FIG. 4G) corresponding to both ends of the clamping portion 135a, and two rotation limiting mechanisms 135d (see FIG. 4G) corresponding to both ends of the clamping portion 135b. The rotation limiting mechanism 135c is set on an inner sidewall of the first side 133b1 of the opening 133b. The rotation limiting mechanism 135d is set on the inner sidewall of the first side 133b1 of the opening 133b. In some embodiments, the clamping portions 135a and 135b are plate-shaped and are horizontally spaced by a first distance D1 (see FIG. 4G). In some embodiments, the rotation limiting mechanisms 135c and 135d are arc-shaped grooves with a curvature of about 90 degrees and protrude towards each other. Both ends of the clamping portion 135a have an axis 135al (see FIG. 4G) and a slider 135a2 (see FIG. 4G). The clamping portion 135a rotates based on the axis 135al and is limited to rotate within an arc-shaped path through the slider 135a2. Similarly, both ends of the clamping portion 135b have an axis 135b1 (see FIG. 4G) and a slider 135b2 (see FIG. 4G). The clamping portion 135b rotates based on the axis 135b1 and is limited to rotate within an arc-shaped path through the slider 135a2.

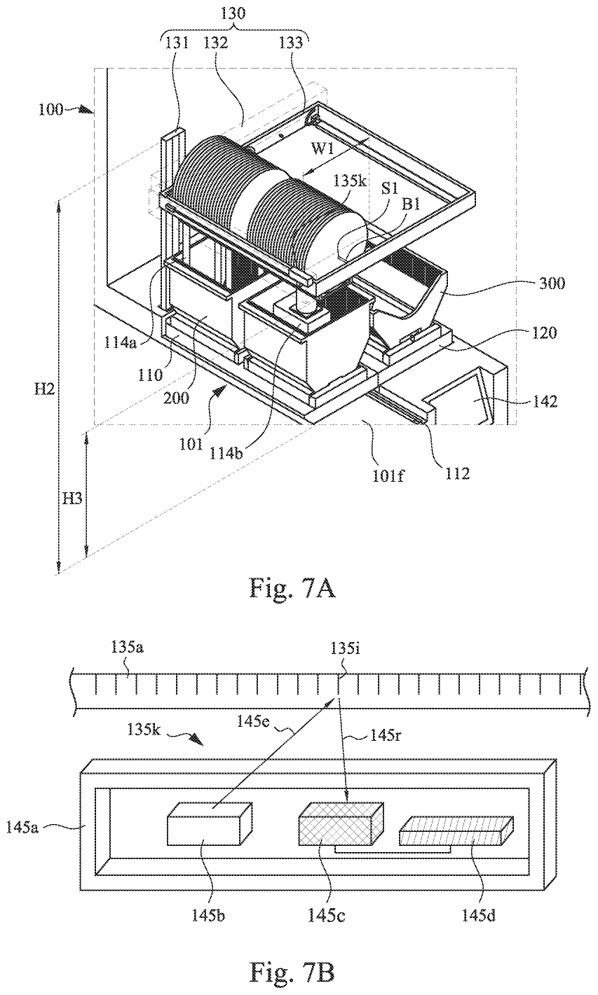

When the clamping portions 135a and 135b (see FIG. 4G) are in a vertical state at first ends 135c1 and 135d1 (see FIG. 4G) of the rotation limiting mechanisms 135c and 135d, the first distance D1 between the clamping portions 135a and 135b will be greater than a widest position S1 (see FIG. 7A) of the wafer W in the vertical direction. When the clamping portions 135a and 135b are in a horizontal state at second ends 135c2 and 135d2 (see FIG. 4G) of the rotation limiting mechanisms 135c and 135d, the first distance D1 between the clamping portions 135a and 135b will be less than the widest position S1 of the wafer W in the vertical direction. The clamping portions 135a and 135b of the clamping structure 135 also have a plurality of slots 135i (see FIG. 4G), which are arranged along the extension direction of the horizontal movement guide rail 112 (see FIGS. 4A, 4B, and 4D) to vertically position the wafer W over the clamping portions 135a and 135b, respectively.

In detail, the clamping structure 136 (see FIG. 4G) has a clamping portion 136a (see FIG. 4G), a clamping portion 136b (see FIG. 4G), two rotation limiting mechanisms 136c (see FIG. 4G) corresponding to both ends of the clamping portion 136a, and two rotation limiting mechanisms 136d (see FIG. 4G) corresponding to both ends of the clamping portion 136b. The rotation limiting mechanism 136c is set on an inner sidewall of the second side 133b2 of the opening 133b. The rotation limiting mechanism 136d is set on the inner wall of the second side 133b2 of the opening 133b. In some embodiments, the clamping portions 136a and 136b are plate-shaped and are horizontally spaced by a second distance D2 (see FIG. 4G). In some embodiments, the rotation limiting mechanisms 136c and 136d are arc-shaped grooves with a curvature of about 90 degrees and protrude towards each other. Both ends of the clamping portion 136a have an axis 136al (see FIG. 4G) and a slider 136a2 (see FIG. 4G). The clamping portion 136a rotates based on the axis 136a1 and is limited to rotate within an arc-shaped path through the slider 136a2. Similarly, both ends of the clamping portion 136b have an axis 136b1 (see FIG. 4G) and a slider 136b2 (see FIG. 4G). The clamping portion 136b rotates based on the axis 136b1 and is limited to rotate within an arc-shaped path through the slider 136a2.

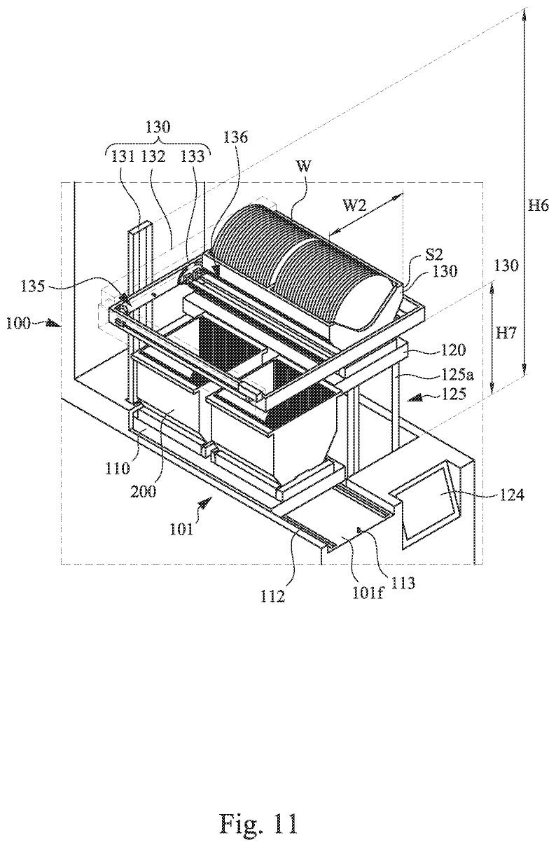

When the clamping portions 136a and 136b (see FIG. 4G) are in a vertical state at first ends 136c1 and 136d1 (see FIG. 4G) of the rotation limiting mechanisms 136c and 136d, the second distance D2 between the clamping portions 136a and 136b will be greater than a widest position S2 (see FIG. 11) of the second wafer carrier 300 in the vertical direction. When the clamping portions 136a and 136b are in a horizontal state at second ends 136c2 and 136d2 (see FIG. 4G) of the rotation limiting mechanisms 136c and 136d, the second distance D2 between the clamping portions 136a and 136b will be less than the widest position S2 of the second wafer carrier 300 in the vertical direction. The width W2 (see FIG. 11) of the second wafer carrier 300 is greater than the width W1 of the wafer W.

In some embodiments, the gripper 130 also includes a wafer sensor 135j (see FIG. 4G), a wafer sensor 136j (see FIG. 4G), and a wafer detection device 135k (see FIG. 4G). The wafer sensor 135j is installed on the sidewall of the opening 133b of the frame 133a and is positioned between the clamping portions 135a and 135b of the clamping structure 135. The wafer sensor 135j can align with the position between the clamping portions 135a and 135b to sense whether the wafer W is clamped on the clamping structure 135. The wafer sensor 136j is installed on the sidewall of the opening 133b of the frame 133a and is positioned between the clamping portions 136a and 136b of the jig 136. The wafer sensor 136j can align with the position between the clamping portions 136a and 136b to sense whether the wafer W is loaded in the second wafer carrier 300. In some embodiments, the wafer sensor 135j and/or wafer sensor 136j can be a diffuse-reflective sensor (or diffused sensor) or a thru-beam sensor. For example, the wafer sensor 135j and/or wafer sensor 136j can function by emitting a light beam B1, usually infrared, towards the target (e.g., the wafer W). When the emitted beam strikes the wafer W, it is scattered in various directions. A portion of this scattered or diffused light is reflected back to the sensor where it is received and detected. In addition, the wafer sensor 135j and/or wafer sensor 136j can operate using two separate components: a transmitter mounted on a first sidewall of the opening 133b, and a receiver mounted on a second sidewall of the opening 133b opposite to the first sidewall.

The wafer detection device 135k can be installed on the frame 133a. After the clamping structure 135 grasps the wafer W, the wafer detection device 135k is configured to move along the extension direction of the horizontal movement guide rail 112 to scan the slots 135i of the clamping portions 135a and 135b, thereby detecting which slots 135i have wafers W and which slots 135i do not (i.e., empty). In some embodiments, the wafer detection device 135k can be a light intensity sensor. In some embodiments, the wafer detection device 135k can also interchangeably be referred to as a metrology device.

In some embodiments, the automated mechanism platform apparatus 100 can have an operation monitoring screen 140 (see FIG. 4A) and a control panel 142 (see FIG. 4A). The operation monitoring screen 140 can be installed on the carrying platform 101 to display the current execution stage of the automated mechanism platform apparatus 100 and the status of each execution stage. If an anomaly occurs during an execution stage, the operation monitoring screen 140 can send out a warning signal to notify the staff to stop the operation of the automated mechanism platform apparatus 100. The control panel 142 is installed on the carrying platform 101 to provide personnel with operations for the automated mechanism platform apparatus 100, such as starting or stopping the operation of the automated mechanism platform apparatus 100.

Referring back to FIG. 1B, the method M then proceeds to block S1031 where a first wafer carrier is placed on a first wafer carrier support base of an automated mechanism platform apparatus, the first wafer carrier has at least one wafer therein, and the wafer has the dielectric layer formed on the first feature over the semiconductor substrate. With reference to FIG. 5, in some embodiments of block S1031, at least one first wafer carrier 200 loaded with wafer W is placed on at least one opening 110b (see FIG. 4E) of the first wafer carrier support base 110 of the automated mechanism platform apparatus 100. After the first wafer carrier 200 is placed on the first wafer carrier support base 110, the silent drag chain 102a (see FIG. 4B) of the horizontal moving module 102 (see FIG. 4B) actuates the horizontal movement guide rail 112 (see FIG. 4B), causing the first wafer carrier support base 110 to move along the extension direction of the horizontal movement guide rail 112 towards the gripper 130, until it is positioned under the gripper 130.

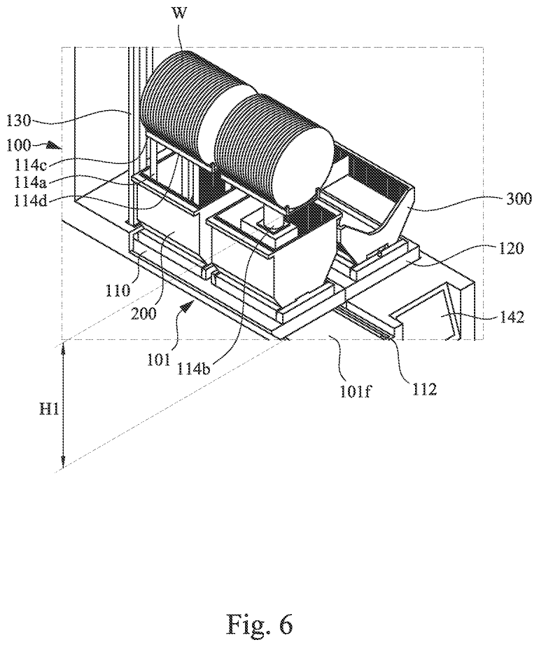

Referring back to FIG. 1B, the method M then proceeds to block S1032 where a first placement bracket of the automated mechanism platform apparatus is used to lift the wafer from the first wafer carrier, allowing the wafer to leave the first wafer carrier. With reference to FIG. 6, in some embodiments of block S1032, when the first wafer carrier 200 is placed on the first wafer carrier support base 110, the placement platform 114c of the first placement bracket 114 can support the wafer W in the first wafer carrier 200 through the opening facing the first wafer carrier support base 110 and position the wafer W in the slots 114d of the placement platform 114c. Subsequently, the silent drag chain 103a (see FIG. 4B) of the lifting module 103 is actuated by the electric cylinder lifting mechanism 103b (see FIG. 4B) to vertically lift the bracket 114a. This makes the bracket 114a drive the placement platform 114c to move vertically upwards until the placement platform 114c is at the first height H1 relative to the carrying surface 101f of the carrying platform 101. Consequently, the wafer W is lifted from the first wafer carrier 200.

Subsequently, the rotor 114b of the first placement bracket 114 can rotate the placement platform 114c to change the orientation of the wafer W relative to the first wafer carrier support base 110. In some embodiments, the rotor 114b can actuate the placement platform 114c to rotate 180 degrees relative to the first wafer carrier support base 110. As a result, the wafer W can enter the processing apparatus 400 in the rotated orientation for processing, reducing the chances of defects occurring on the wafer W during the process. In some embodiments, a first group including wafers W over a first one the placement platforms 114c will be rotated, while a second group of wafers W over a second one the placement platforms 114c will not be rotated. This ensures that the front sides of the first group of wafers W over the first one of the placement platforms 114c may face the front sides of the second group of wafers W over the second one of the placement platforms 114c, or the back sides of the first group of wafers W over the first one of the placement platforms 114c may face the back sides of the second group of wafers W over the second one of the placement platforms 114c. In some embodiments, all the wafers W carried in multiple first wafer carriers 200 will be rotated.

Referring back to FIG. 1B, the method M then proceeds to block S1033 where the wafer is grabbed from the first placement bracket using the gripper of the automated mechanism platform apparatus. With reference to FIGS. 7A and 7B, in some embodiments of block S1033, the lifting gripper platform 133 (see FIG. 7A) moves horizontally through the horizontal movement guide rail 132, aligning the clamping structure 135 (see FIGS. 3, 4A, 4B, and 4G) with the first placement bracket 114 (see FIG. 6). At this moment, the clamping portions 135a and 135b (see FIG. 4G) of the clamping structure 135 are horizontally spaced by the first distance D1 that is greater than the widest position S1 of the wafer W in the vertical position. This allows the widest position S1 of the wafer W to pass from bottom to top through the space between the clamping portions 135a and 135b.

Subsequently, the lifting gripper platform 133 (see FIG. 7A) can descend via the lifter 131, causing the clamping structure 135 to move from a second height H2 to a third height H3 relative to the carrying surface 101f of the carrying platform 101, in which the second height H2 is above the wafer W, and the third height H3 is below the widest position S1 of the wafer W. This arrangement allows the widest position S1 of the wafer W to pass from bottom to top between the clamping portions 135a and 135b.

Subsequently, the clamping portions 135a and 135b (see FIG. 4G) of the clamping structure 135 rotate and are positioned horizontally at the second ends 135c2 and 135d2 (see FIG. 4G) of the rotation limiting mechanisms 135c and 135d, respectively. This creates a first distance D1 (see FIG. 4G) between them that is smaller than the widest dimension of the wafer W, allowing them to block and support both sides of the wafer W. Subsequently, the lifting gripper platform 133 (see FIG. 7A) can rise via the lifter 131, allowing the clamping structure 135 (see FIG. 4G) to physically touch and support both sides of the wafer W. This action can grab the wafer W from the first placement bracket 114 (see FIG. 6) and positions it in the slots 135i (see FIG. 4G) of the clamping structure 135.

Subsequently, the wafer detection device 135k moves along the extension direction of the horizontal movement guide rail 112 to scan the slots 135i (see FIG. 4G) of the clamping portion 135a (see FIG. 4G) and the clamping portion 135b (see FIG. 4G), thereby detecting which slots 135i have a wafer W and which slots 135i are empty (i.e., vacant). In some embodiments, the wafer detection device 135k (see FIG. 7B) includes a housing 145a (see FIG. 7B), a light emitting unit 145b (see FIG. 7B) located inside the housing 145a, a light receiving unit 145c (see FIG. 7B) located inside the housing 145a adjacent to the light emitting unit 145b, and a sensor control circuit 145d (see FIG. 7B). In some configurations, the light emitting unit 145b is designed to produce (i.e., emit) a light beam 145e (see FIG. 7B) towards the slots 135i of the clamping portions 135a and 135b (see FIG. 7A). For instance, the light emitting unit 145b generates a light beam 145e directed towards the slots 135i of the clamping portions 135a and 135b. In some configurations, the light emitting unit 145b could be a laser or some other suitable radiation source. In certain instances, the light beam 145e can be electromagnetic radiation or a laser beam. The light receiving unit 145c is configured to measure the intensity of the reflected portion 145r of the light beam 145e that is reflected back from the wafer W. For example, because the first slot 135i holds the wafer W, the light receiving unit 145c measures the reflected portion 145r (see FIG. 7B) of the light beam 145e that is reflected from the wafer W in slot 135i. In some configurations, the light receiving unit 145c can alternately be referred to as a detection sensor or a light intensity sensor. In some embodiments, the light receiving unit 145c could be a photosensitive device (e.g., a phototransistor, a photodiode, a fiber optic pressure sensor, or other suitable components).

In some configurations, the sensor control circuit 145d (see FIG. 7B) is coupled to the light receiving unit 145c (see FIG. 7B). By detecting the light intensity of the optical signal, the sensor control circuit 145d can determine whether slot 135i is empty or occupied by wafer W. For example, if the first slot 135i is occupied by wafer W, the light receiving unit 145c will receive a light signal from the wafer W and detect the light intensity of the wafer W's light signal. Consequently, the light signal from the wafer W might be close to a reference light signal, enabling the sensor control circuit 145d to determine the difference in light intensity between the reflected portion 145r of the light beam 145e and the reference light signal within an acceptable value range, subsequently indicating the occupied state of the slot 135i. As a result, the sensor control circuit 145d can generate wafer positioning results, listing which slots 135i are occupied by wafer W and which slots 135i are empty, thus pinpointing the location of wafer W in the slot 135i. Moreover, the sensor control circuit 145d can be configured to determine if the grasping status of the slots 135i of the clamping portions 135a and 135b is acceptable. If the grasping (or storage) status of the slots 135i of the clamping portions 135a and 135b is determined to be unacceptable, the sensor control circuit 145d will issue a warning signal and halt the operation of the automated mechanism platform apparatus 100.

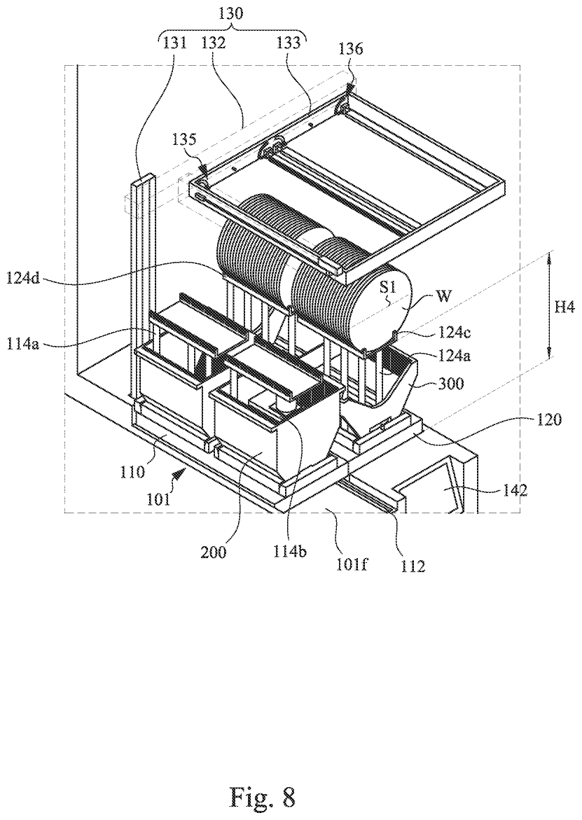

Referring back to FIG. 1B, the method M then proceeds to block S1034 where the wafer is moved from the gripper to a second placement bracket of the automated mechanism platform apparatus. With reference to FIG. 8, in some embodiments of block S1034, the second wafer carrier 300 (see FIG. 5) is placed on the second wafer carrier support base 120 (see FIG. 5) of the automated mechanism platform apparatus 100. The silent drag chain 104a (see FIG. 4B) of the lifting module 104 (see FIGS. 4B and 4G) is actuated by the electric cylinder lifting mechanism 104b (see FIG. 4B) to vertically raise the bracket 124a, making the bracket 124a drive the placement platform 124c to move upwards vertically, until the placement platform 124c is at the fourth height H4 relative to the carrying surface 101f of the carrying platform 101. In some embodiments, the fourth height H4 of the placement platform 124c can be the same as the first height H1 of the placement platform 114c. In some embodiments, the fourth height H4 of the placement platform 124c can be higher or lower than the first height H1 of the placement platform 114c.

The lifting gripper platform 133 moves horizontally through the horizontal moving guide rail 132, aligning the clamping structure 135 with the second placement bracket 124. Subsequently, the lifting gripper platform 133 moves downward vertically through the lifter 131, making the placement platform 124c physically touch and support both sides of the wafer W, to lift the wafer W off the clamping structure 135, thus separating the wafer W from contact with the clamping structure 135. The wafer W can be positioned in the slots 124d on the placement platform 124c.

Subsequently, the clamping portions 135a and 135b (see FIG. 4G) of the clamping structure 135 rotate to be vertically oriented at the first ends 135cl and 135dl (see FIG. 4G) of the rotation limiting mechanisms 135c and 135d. The distance D1 (see FIG. 4G) between the clamping portions 135a and 135b (see FIG. 4G) is greater than the widest dimension of the wafer W in the vertical direction, allowing the widest position S1 of the wafer W to pass vertically downwards through the space between the clamping portions 135a and 135b.

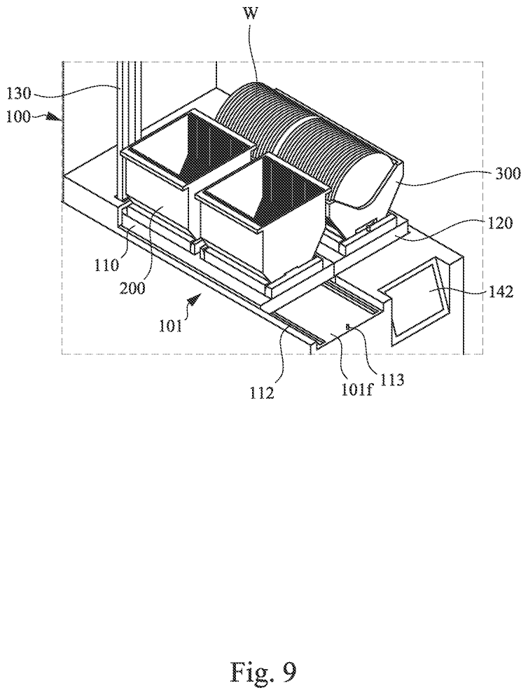

Referring back to FIG. 1B, the method M then proceeds to block S1035 where the second placement bracket is used to settle the wafer into a second wafer carrier over a second wafer carrier support base of the automated mechanism platform apparatus. With reference to FIG. 9, in some embodiments of block S1035, the bracket 124a (see FIG. 8) is actuated to move vertically downward, making the bracket 124a (see FIG. 8) drives the placement platform 124c (see FIG. 8) to move downwards vertically. The widest position S1 (see FIG. 8) of the wafer W in the vertical direction can pass from top to bottom through the space between the clamping portions 135a and 135b (see FIG. 4G) until it settles into the second wafer carrier 300.

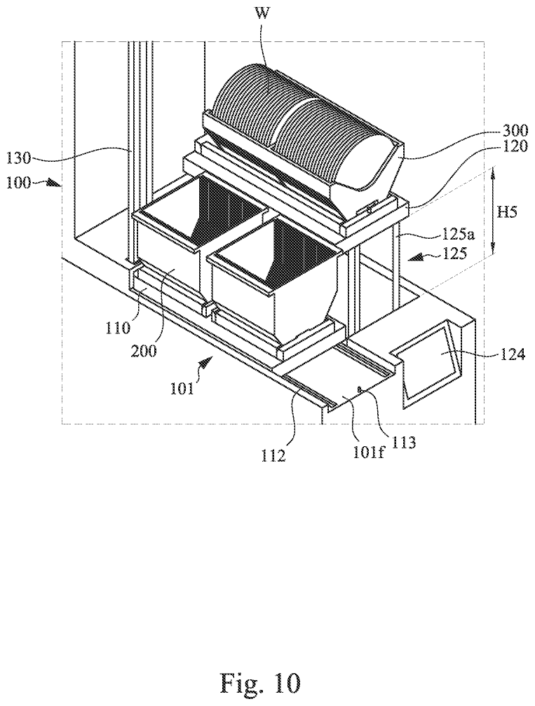

Referring back to FIG. 1B, the method M then proceeds to block S1036 where the second wafer carrier support base is used to lift the second wafer carrier loaded with the wafer. With reference to FIG. 10, in some embodiments of block S1036, the silent drag chain 105a (see FIG. 4C) of the lifting module 105 (see FIGS. 4C and 4H) is actuated by the electric cylinder lifting mechanism 105b (see FIG. 4C) to vertically raise the bracket 125a of the wafer carrier lifting device 125. This makes the bracket 125a drive the second wafer carrier support base 120 to move upwards vertically, until the second wafer carrier support base 120 is at the fifth height H5 relative to the carrying surface 101f of the carrying platform 101. In some embodiments, the fifth height H5 of the second wafer carrier support base 120 can be the same as the first height H1 of the placement platform 114c or the fourth height H4 of the placement platform 124c. In some embodiments, the fifth height H5 of the second wafer carrier support base 120 can be higher or lower than the first height H1 of the placement platform 114c or the fourth height H4 of the placement platform 124c.

Referring back to FIG. 1B, the method M then proceeds to block S1037 where the gripper is used to grab the second wafer carrier loaded with wafer from the second wafer carrier support base. With reference to FIG. 11, in some embodiments of block S1037, the lifting gripper platform 133 will move horizontally through the horizontal moving guide rail 132, aligning the clamping structure 136 with the second placement bracket 124. At this time, the clamping portions 136a and 136b (see FIG. 4G) of the clamping structure 136 will be in a vertical position, creating a second distance D2 (see FIG. 4G) between the clamping portions 136a and 136b and greater than the widest dimension of the second wafer carrier 300 in the vertical direction. This allows the widest position S2 of the second wafer carrier 300 to pass from bottom to top through the space between the clamping portions 136a and 136b (see FIG. 4G).

Subsequently, the lifting gripper platform 133 can descend via the lifter 131, causing the clamping structure 136 to move from a sixth height H6, relative to the carrying surface 101f of the carrying platform 101, to a seventh height H7, in which the sixth height H6 is above the second wafer carrier 300, while the seventh height H7 is below the widest position S2 of the second wafer carrier 300, allowing the widest position S2 of the second wafer carrier 300 to pass from bottom to top between the clamping portions 136a and 136b (see FIG. 4G). In some embodiments, the sixth height H6 of the clamping structure 136 may be the same as the second height H2 of clamping structure 135. In some cases, the sixth height H6 of the clamping structure 136 can be higher or lower than the second height H2 of clamping structure 135. In some methods, the seventh height H7 of the clamping structure 136 can be the same as the third height H3 of clamping structure 135. In some instances, the seventh height H7 of the clamping structure 136 can be higher or lower than the third height H3 of clamping structure 135.

Subsequently, the clamping portions 136a and 136b (see FIG. 4G) of the clamping structure 136 rotate to be positioned at the second ends 136c2 and 136d2 (see FIG. 4G) of the arc-shaped groove, taking a horizontal position. This changes the second distance D2 (see FIG. 4G) between them to be smaller than the widest dimension (e.g., width W2) of the second wafer carrier 300 in the vertical direction, thus blocking and supporting both sides of the second wafer carrier 300. Subsequently, the lifting gripper platform 133 can rise via the lifter 131, causing the clamping structure 136 to physically touch and support both sides of the second wafer carrier 300, grabbing the second wafer carrier 300 loaded with the wafer W from the second wafer carrier support base 120.

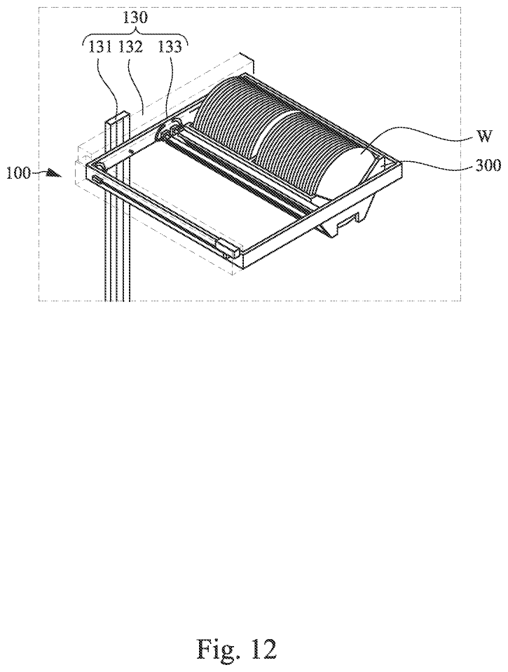

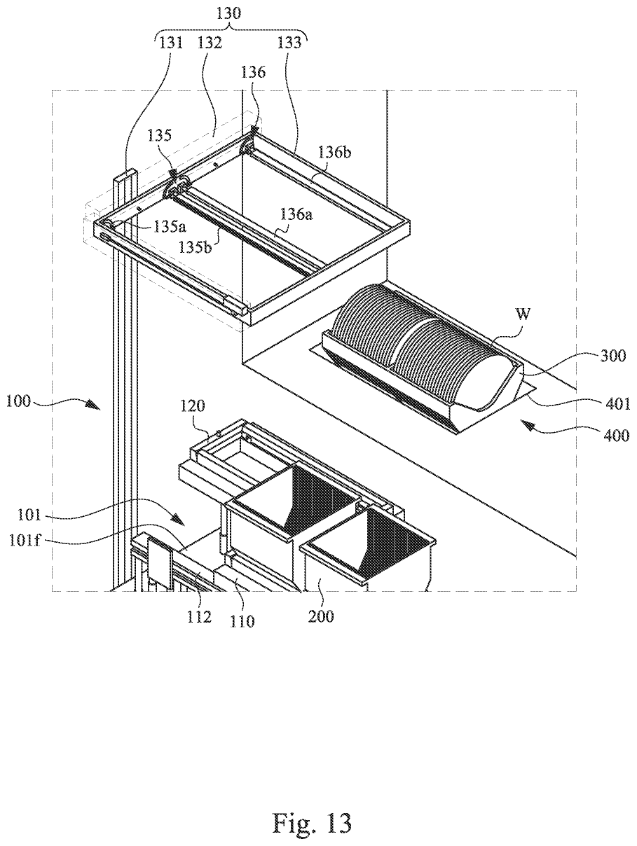

Referring back to FIG. 1B, the method M then proceeds to block S1038 where the second wafer carrier is moved towards the processing apparatus using the gripper. With reference to FIG. 12, in some embodiments of block S1038, the lifting gripper platform 133 can move horizontally towards the processing apparatus 400 through the horizontal moving guide rail 132, aligning the clamping structure 136 with a bearing platform 401 (see FIG. 13) of the processing apparatus 400 (see FIG. 13). This can ensure that the second wafer carrier 300 can be aligned with the bearing platform 401 of the processing apparatus 400.

Referring back to FIG. 1B, the method M then proceeds to block S1039 where the second wafer carrier is placed on a processing apparatus using the gripper. With reference to FIG. 13, in some embodiments of block S1039, the lifting gripper platform 133 can move vertically towards the processing apparatus 400 via the lifter 131, allowing the bearing platform 401 of the processing apparatus 400 to physically touch and support the second wafer carrier 300. This action can lift the second wafer carrier 300 off the clamping structure 136, ensuring it's separated and not in contact with the clamping structure 136.

Subsequently, the clamping portions 136a and 136b of clamping structure 136 will rotate to be positioned at the first ends 136c1 and 136d1 (see FIG. 4G) of the rotation limiting mechanisms 136c and 136d (see FIG. 4G), taking a vertical position. This creates a second distance D2 (see FIG. 4G) between the clamping portions 136a and 136b and greater than the widest dimension of the second wafer carrier 300, allowing the widest position S2 (see FIG. 11) of the second wafer carrier 300 to pass from top to bottom through the space between the clamping portions 136a and 136b. As a result, using the gripper 130, the second wafer carrier 300 can be placed on the bearing platform 401 of the processing apparatus 400.

Referring back to FIG. 1B, the method M then proceeds to block S1040 where a removing process is performed on the wafer. With reference to FIGS. 14A-14C, in some embodiments of block S1040, the removing process P1, such as a wet etch process, can be performed by soaking the wafer W in the process chamber 410 containing a liquid (e.g., the etching solution ES), and the wafer carrier 300 (not shown) is simultaneously soaked in the process chamber 410. FIGS. 14A-14C are diagrammatic cross-sectional views of the processing apparatus 400, such as a wet etch apparatus, at various stages of the removing process P1, such as a wet process, according to some embodiments of the present disclosure. The wafer W includes one or plural semiconductor substrates 510 in FIGS. 2A and 2B. For example, under the control of the controller 460, the etching solution ES is supplied from the etching solution source 440 to the process chamber 410 through the flow control device V41 and the supply line L41. For removing silicon oxide layer, the etching solution ES may be HF and buffered oxide etchant (BOE). In some alternative embodiments, the etching solution ES may be ammonia-peroxide mixture (APM) (e.g., a mixture of NH₄OH, H₂O₂, and water), H₃PO₄, the like, or the combination thereof.

Subsequently, the liquid (e.g., the etching solution ES in FIG. 14A) is drained from the process chamber 410. For example, under the control of the controller 460, the etching solution ES in FIG. 14A is drained from the process chamber 410 (e.g., the inner bath 412 and/or the outer bath 414) through the flow control device V43 and the drain line L43. Subsequently, the inactive solution WS is supplied to the process chamber 410. The inactive solution WS is inactive to the wafer W. For example, the inactive solution WS may be de-ionized (DI) water. For example, after the etching solution ES (referring to FIG. 14A) is drained from the process chamber 410, under the control of the controller 460, the inactive solution WS is supplied from the water source 450 to the process chamber 410 (e.g., the inner bath 412) through the flow control device V42 and the supply line L42.

In FIGS. 14A-14C, the processing apparatus 400 can includes a process chamber 410, wafer holders 420, supplying nozzles 430, an etching solution source 440, a water source 450, a controller 460, a sink tank 470, flow control devices V41-V43, lines L41-L43, and support elements FS. The process chamber 410 stores an etching solution ES. The process chamber 410 can includes an inner bath 412 and an outer bath 414. An etching solution ES overflowing from the inner bath 412 flows into the outer bath 414. The liquid level in the outer bath 414 is maintained lower than the liquid level in the inner bath 412. The wafer holders 420 are disposed in the inner bath 412 for holding the second wafer carrier 300 (not shown in FIGS. 14A-14C) accommodating the wafers W. The process chamber 410 can be fixed in the sink tank 470 by the support elements FS. The sink tank 470 may contain suitable solution BS for buffering etching solution ES. For example, the solution BS may be DI-water.

The supplying nozzles 430 are disposed in the inner bath 412 and fluidly connected to the outer bath 414 by a suitable circulation line with a pump. By driving the pump, a circulation flow of the liquids (e.g., etching solution ES or de-ionized water) is formed, which flows from the outer bath 414 through the circulation line and the supplying nozzles 430 into the inner bath 412. Arrows adjacent the supplying nozzles 430 indicates the flow direction of the etching solution ES coming from the supplying nozzles 430. An etching solution supplying system includes an etching solution source 440, a supply line L41 coupled to the etching solution source 440, and a flow control device V41 coupled to the supply line L41. The etching solution source 440 includes a tank storing the etching solution ES. Via the flow control device V41 and the supply line L41, the etching solution source 440 provides the etching solution ES to the process chamber 410 (e.g., the inner bath 412 and/or the outer bath 414).

A water supplying system includes a water source 450, a supply line L42 coupled to the water source 240, and a flow control device V42 coupled to the supply line L42. The water source 450 includes a tank storing water, such as de-ionized water (DI-water). Via the flow control device V42 and the supply line L42, the water source 450 provides water to the inner bath 412. One or plural drain lines L43 are fluidly couple to a bottom of the inner bath 412 and/or a bottom of the outer bath 414. For example, the inner bath 412 and the outer bath 414 have drain holes at their bottoms, and the drain lines L43 are fluidly coupled to the drain holes. The flow control device V43 is coupled to the drain lines L43. Via the flow control device V43 and the drain lines L43, liquids (e.g., the etching solution ES) can be drained out from the inner bath 412 and/or the outer bath 414.

In present embodiments, the flow control devices V41-V43 may be pneumatic valves. In some other embodiments, the flow control devices V41-V43 may be a shutoff valves, a flow control valves, flowmeters, the like, or the combination thereof. The controller 460 may control the flow control devices V41-V43 for adjusting the flow rates of the lines L41-L43. The controller 460 may include a computer-readable storage medium and a processor coupled to the computer-readable storage medium. The computer-readable storage medium stores program that controls various steps of the wet processing method M performed in the processing apparatus 400. The controller 460 controls the operations of the processing apparatus 400 by using the processor reading out and executing the program stored in the storage medium. The program may be one that has been stored in the computer-readable storage medium, or may be one that has been installed to the storage medium of the controller 460.

The wafer W, after undergoing its process in the apparatus 400, is transferred back from the second wafer carrier 300 to the first wafer carrier 200 through the automation mechanism platform apparatus 100, and this transferring back process can be the reverse of the steps shown in FIGS. 5-13. This backward flow can ensure that the wafer W is safely and efficiently returned to its original position after the removing process P1. Instead of initiating a removing process like a wet etch, the wafer W is taken out of the process chamber 410 from the processing apparatus 400, having completed the procedure.

Subsequently, using the gripper 130, the second wafer carrier 300, which holds the wafer W, can be lifted off the bearing platform 410 of the processing apparatus 400. Subsequently, the lifting gripper platform 133 can move the wafer carrier 300 away from the processing apparatus 400, back towards the automation mechanism platform apparatus 100. Subsequently, the lifting gripper platform 133 can descend, placing the second wafer carrier 300 back onto the second wafer carrier support base 120. Subsequently, the second wafer carrier support base 120, with the wafer-loaded carrier, can be lowered to a predefined position using the lifting module. Subsequently, using the lifting gripper platform 133, the wafer W can be gripped and lifted out of the second wafer carrier 300, preparing for its transfer. Subsequently, the wafer W is then moved horizontally and vertically, aligning it with the first wafer carrier 200. The wafer W is then placed on the first placement bracket 114. Subsequently, the first placement bracket 114 can retrieve the wafer W from the gripper 130. Subsequently, the first wafer carrier 200 can receive the wafer W from the first placement bracket 114 and returns it to its original starting position or location before the processing began.

After the wafer W is transferred back to the first wafer carrier 200 via the automation mechanism platform apparatus 100, the wafer carrier 200 with the wafer W can be utilized as a transport medium to move the wafer W to other apparatuses, and additional processes may be performed on the wafer W. One such process may include forming structures on the wafer W, as illustrated in FIG. 2C.

Referring back to FIG. 1A, the method M then proceeds to block S104 where a second feature (e.g., metal feature) is formed over the first feature. With reference to FIG. 2C, in some embodiments of block S104, gate spacers 550 are formed on opposite sides of the stack of the gate dielectric 531′ and the gate electrode 532. An etch stop layer 560 and an interlayer dielectric layer 570 can be deposited over the semiconductor substrate 510 on the wafer W. Contacts 580 can be formed in the interlayer dielectric layer 570 over the gate electrode 532 and source/drain regions of the active regions 510a. An interlayer dielectric layer 572 can be deposited over the contact 580. Subsequently, the interlayer dielectric layer 572 can be patterned to formed an opening 572a exposing the contact 580. In some embodiments, the gate spacers 550 may be made of silicon nitride or silicon oxynitride, although any suitable material, such as low-dielectric constant (low-k) materials having a k-value less than about 3.5, may be utilized. In some embodiments, the etch stop layer 560 may be formed of a dielectric material, such as silicon nitride, silicon oxide, silicon oxynitride, or the like, having a high etching selectivity from the etching of the interlayer dielectric layer 570. In some embodiments, the interlayer dielectric layer 570 and/or 572 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, materials of the contacts 580 may include Cu, Co, Ru, Pt, Al, W, Ti, TaN, TiN, or any combinations thereof.

When manufacturing semiconductor devices, the surface of exposed conductive materials, such as the contact 580, can naturally react with the oxygen in the environment, resulting in the formation of a very thin layer of oxide, commonly referred to as “native oxide.” The native oxide often acts as an insulator. If the native oxide left in place, it can introduce unwanted resistance at the interface where other conductive layers (e.g., a conductive layer 582) are formed atop the contact 580. This added resistance can degrade the performance of the device. In some embodiments, the native oxides may interfere with the ability of subsequent layers to adhere properly to the contact 580. Once the native oxide is removed and the contact 580 is clean, the conductive layer 582 can be formed on a top of the contact 580. The removal of the native oxide ensures that these features have good electrical contact with the contact 580, ensuring optimal device performance.

Referring back to FIG. 1A, the method M then proceeds to block S105 where an oxide layer (e.g., native oxide) is formed over the second feature (e.g., the contact 580). With reference to FIG. 2C, in some embodiments of block S105, the exposure of the contact 580 to ambient conditions can lead to the formation of an oxide layer 581 (e.g., native oxide). The oxide layer 581 may form because many metals and semiconductors will naturally oxidize when exposed to air.

Referring back to FIG. 1A, the method M then proceeds to block S106 where the oxide layer (e.g., native oxide) is removed from the second feature (e.g., the contact 580). With reference to FIG. 2D, in some embodiments of block S106, the oxide layer 581 (e.g., the native oxide) can removed from the contact 580 by the removing process P2, such as a wet etch process. The removing process P2 can be performed in a process chamber 410 (see FIGS. 14A-14C) of the processing apparatus 400. By the wet etch process, the oxide layer 581 (see to FIG. 2C) can be removed. During the removing process P2, the wafer W, along with its wafer carrier, is placed inside the process chamber 410. If the wafer carrier, which is used for transporting wafer W between apparatuses, is inserted into the process chamber 410, it might damage the wafer carrier and potentially contaminate the wafer W. Therefore, this disclosure employs the automation mechanism platform apparatus 100 to transfer the wafer W to a wafer carrier that can withstand the removing process P2 before placing it into the process chamber 410. This ensures that the wafer carrier is not damaged and the wafer W remains uncontaminated. The automation mechanism platform apparatus 100 can serve to efficiently transfer the wafers W between wafer carriers, ensuring they are placed in suitable wafer carriers that can withstand specific processes, such as the removing process P2. The automation mechanism platform apparatus 100 can aim to prevent potential damage to the carriers and contamination of the wafers W, enhancing the overall efficiency and safety of wafer processing.

The process of utilizing the automation mechanism platform apparatus 100 to transfer wafer W from wafer carrier 200 to wafer carrier 300 and subsequently introducing it into the processing apparatus 400 to perform the removing process P2 can substantially mirror the method depicted in FIGS. 5-14C. Subsequently, a conductive layer 582 (see FIG. 2E) can be formed over the contact 580. In some embodiments, materials of the conductive layer 582 may include Cu, Co, Ru, Pt, Al, W, Ti, TaN, TiN, or any combinations thereof.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an automated mechanism platform apparatus to transfer wafers between diverse wafer carriers. Furthermore, this automated mechanism platform apparatus can be equipped to convey the wafer directly into the chamber of a processing apparatus, such as an acid trough apparatus. By these functionalities, the automated mechanism platform apparatus can boost the manufacturing efficiency of semiconductor structure. The automated mechanism platform apparatus can minimize human intervention, thus reducing the potential for human-induced errors, mishandling, or contamination. Automated systems maintain a consistent and controlled environment, ensuring wafers are handled with precision, reducing the chances of physical damage. Moreover, by eliminating manual transfers, the automated mechanism platform apparatus can decrease the exposure of wafers to contaminants, ensuring their integrity throughout the process. Operating on electric control, the automated mechanism platform apparatus can offer visualized operational data, encapsulates a modular approach to its diverse functions, and boasts a streamlined design.

In some embodiments, a method includes placing a first wafer carrier on a first wafer carrier support base of an automated mechanism platform apparatus, the first wafer carrier accommodating a plurality of wafers; grapping the wafers from the first wafer carrier by a gripper of the automated mechanism platform apparatus; moving the wafers from the gripper to a second wafer carrier placing on a second wafer carrier support base of the automated mechanism platform apparatus; grapping the second wafer carrier with the wafers from the second wafer carrier support base by the gripper; transferring the second wafer carrier with the wafers from the gripper to a processing apparatus. In some embodiments, the step of grapping the wafers from the first wafer carrier comprises: lifting the wafers from the first wafer carrier through a back-side of the first wafer carrier with a placement bracket, allowing the wafers to leave the first wafer carrier from a front-side of the first wafer carrier; clamping the wafers from the placement bracket by the gripper; rising the wafers from the placement bracket. In some embodiments, the step of moving the wafers from the gripper to the second wafer carrier comprises: lifting a placement platform through a back-side of the second wafer carrier to a position higher than the second wafer carrier; placing the wafers on the placement platform from the gripper; downwardly moving the placement platform to settle the wafers in the second wafer carrier from a front-side of the second wafer carrier. In some embodiments, the step of grapping the second wafer carrier with the wafers from the second wafer carrier support base comprises: lifting the second wafer carrier support base having the second wafer carrier thereon with the wafers; clamping the second wafer carrier by the gripper; rising the second wafer carrier from the second wafer carrier support base. In some embodiments, transferring the second wafer carrier with the wafers from the gripper to the processing apparatus comprises: moving the second wafer carrier vertically and horizontally towards the processing apparatus with the gripper; releasing the second wafer carrier from the gripper to the processing apparatus. In some embodiments, the method further includes: after placing the first wafer carrier on the first wafer carrier support base and prior to grapping the wafers from the first wafer carrier, rotating the wafers along a vertical axis to change an orientation of the wafers relative to the first wafer carrier support base. In some embodiments, the gripper comprises: a lifter extending along a vertical direction; a horizontal movement guide rail liftable by the lifter; and a lifting gripper platform movably coupled to the horizontal movement guide rail. In some embodiments, the method further includes: after grapping the wafers from the first wafer carrier by the gripper, detecting a storage status of slots on the gripper using a metrology device positioned on the gripper; determining whether the storage status of the slots on the gripper is acceptable. In some embodiments, the second wafer carrier is made of a different material than the first wafer carrier. In some embodiments, the method further includes: performing a wet etch process on the wafers accommodating in the second wafer carrier by the processing apparatus.

In some embodiments, a method includes grapping a plurality of first wafers from a first wafer carrier over a first wafer carrier support base of an automated mechanism platform apparatus, wherein the step of grapping the first wafers is performed by a gripper of the automated mechanism platform apparatus; moving the first wafers from the gripper to a second wafer carrier over a second wafer carrier support base of the automated mechanism platform apparatus, wherein the second wafer carrier is made of a different material than the first wafer carrier; transferring the second wafer carrier with the first wafers from the second wafer carrier support base to a wet etch apparatus by the gripper; performing a wet etch process on the first wafers. In some embodiments, the method further includes: prior to grapping the first wafers from the first wafer carrier, detecting whether the first wafer carrier is disposed on the first wafer carrier support base by a wafer carrier positioning detection device. In some embodiments, the method further includes: prior to moving the first wafers from the gripper to the second wafer carrier, detecting whether the second wafer carrier is disposed on the second wafer carrier support base by a wafer carrier positioning detection device. In some embodiments, the method further includes: grapping a plurality of second wafers from a third wafer carrier over the first wafer carrier support base by the gripper, wherein the step of grapping the second wafers is performed simultaneously with the step of grapping the first wafers. In some embodiments, the method further includes: moving the second wafers from the gripper to the second wafer carrier, wherein the step of moving the second wafers is performed simultaneously with the step of moving the first wafers.

In some embodiments, an apparatus includes a carrying platform, a first wafer carrier support base, a second wafer carrier support base, a first placement bracket, a third bracket, and a gripper. The first wafer carrier support base is over a carrying platform. The second wafer carrier support base is over the carrying platform and adjacent to the first wafer carrier support base. The first placement bracket includes a first bracket and a first placement platform supported on the first bracket and enclosed by the first wafer carrier support base, and the first bracket initiates a first vertical motion of the first placement platform relative to the first wafer carrier support base. The second placement bracket includes a second bracket and a second placement platform supported on the second bracket and enclosed by the second wafer carrier support base, and the second bracket initiates a second vertical motion of the second placement platform relative to the second wafer carrier support base. The third bracket supports the second wafer carrier support base, and the third bracket initiates a third vertical motion of the second wafer carrier support base relative to the carrying platform. The gripper over the carrying platform, and the gripper includes a lifter extending along a first direction, a horizontal movement guide rail liftable by the lifter and extending along a second direction perpendicular to the first direction, and a lifting gripper platform movably coupled to the horizontal movement guide rail. In some embodiments, the apparatus further includes a rotor between the first bracket and the first placement platform, the rotor initiating a rotation of the first placement platform relative to the first bracket. In some embodiments, the lifting gripper platform includes a frame and a first clamping structure mounted on the frame. The first clamping structure includes a pair of first clamping portions laterally spaced apart from each other; a pair of first rotation limiting mechanisms on opposite ends of a first one of the pair of first clamping portions; and a pair of second rotation limiting mechanisms on opposite ends of a second one of the pair of first clamping portions, the first and second rotation limiting mechanisms allowing rotations of the pair of first clamping portions to adjust a first lateral distance therebetween. In some embodiments, the lifting gripper platform further includes a second clamping structure mounted on the frame and arranged with the first clamping structure along the second direction. The second clamping structure a pair of second clamping portions laterally spaced apart from each other; a pair of third rotation limiting mechanisms on opposite ends of a first one of the pair of second clamping portions; and a pair of fourth rotation limiting mechanisms on opposite ends of a second one of the pair of second clamping portions, the third and fourth rotation limiting mechanisms allowing rotations of the pair of second clamping portions to adjust a second lateral distance therebetween. In some embodiments, the second lateral distance is greater than the first lateral distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
placing a first wafer carrier on a first wafer carrier support base of an automated mechanism platform apparatus, the first wafer carrier accommodating a plurality of wafers;
grapping the wafers from the first wafer carrier by a gripper of the automated mechanism platform apparatus;
moving the wafers from the gripper to a second wafer carrier placing on a second wafer carrier support base of the automated mechanism platform apparatus;
grapping the second wafer carrier with the wafers from the second wafer carrier support base by the gripper; and
transferring the second wafer carrier with the wafers from the gripper to a processing apparatus.

2. The method of claim 1, wherein the step of grapping the wafers from the first wafer carrier comprises:
lifting the wafers from the first wafer carrier through a back-side of the first wafer carrier with a placement bracket, allowing the wafers to leave the first wafer carrier from a front-side of the first wafer carrier;
clamping the wafers by the gripper; and.
rising the wafers from the placement bracket.

3. The method of claim 1, wherein the step of moving the wafers from the gripper to the second wafer carrier comprises:
lifting a placement platform through a back-side of the second wafer carrier to a position higher than the second wafer carrier;
placing the wafers on the placement platform from the gripper; and
downwardly moving the placement platform to settle the wafers in the second wafer carrier from a front-side of the second wafer carrier.

4. The method of claim 1, wherein the step of grapping the second wafer carrier with the wafers from the second wafer carrier support base comprises:
lifting the second wafer carrier support base having the second wafer carrier thereon with the wafers;
clamping the second wafer carrier by the gripper; and
rising the second wafer carrier from the second wafer carrier support base.

5. The method of claim 1, wherein transferring the second wafer carrier with the wafers from the gripper to the processing apparatus comprises:
moving the second wafer carrier vertically and horizontally towards the processing apparatus with the gripper; and
releasing the second wafer carrier from the gripper to the processing apparatus.

6. The method of claim 1, further comprising:
after placing the first wafer carrier on the first wafer carrier support base and prior to grapping the wafers from the first wafer carrier, rotating the wafers along a vertical axis to change an orientation of the wafers relative to the first wafer carrier support base.

7. The method of claim 1, wherein the gripper comprises:
a lifter extending along a vertical direction;
a horizontal movement guide rail liftable by the lifter; and
a lifting gripper platform movably coupled to the horizontal movement guide rail.

8. The method of claim 1, further comprising:
after grapping the wafers from the first wafer carrier by the gripper, detecting a storage status of slots on the gripper using a metrology device positioned on the gripper; and
determining whether the storage status of the slots on the gripper is acceptable.

9. The method of claim 1, wherein the second wafer carrier is made of a different material than the first wafer carrier.

10. The method of claim 1, further comprising:
performing a wet etch process on the wafers accommodating in the second wafer carrier by the processing apparatus.

11. A method, comprising:
grapping a plurality of first wafers from a first wafer carrier over a first wafer carrier support base of an automated mechanism platform apparatus, wherein the step of grapping the first wafers is performed by a gripper of the automated mechanism platform apparatus;
moving the first wafers from the gripper to a second wafer carrier over a second wafer carrier support base of the automated mechanism platform apparatus, wherein the second wafer carrier is made of a different material than the first wafer carrier;
transferring the second wafer carrier with the first wafers from the second wafer carrier support base to a wet etch apparatus by the gripper; and
performing a wet etch process on the first wafers.

12. The method of claim 11, further comprising:
prior to grapping the first wafers from the first wafer carrier, detecting whether the first wafer carrier is disposed on the first wafer carrier support base by a wafer carrier positioning detection device.

13. The method of claim 11, further comprising:
prior to moving the first wafers from the gripper to the second wafer carrier, detecting whether the second wafer carrier is disposed on the second wafer carrier support base by a wafer carrier positioning detection device.

14. The method of claim 11, further comprising:
grapping a plurality of second wafers from a third wafer carrier over the first wafer carrier support base by the gripper, wherein the step of grapping the second wafers is performed simultaneously with the step of grapping the first wafers.

15. The method of claim 14, further comprising:
moving the second wafers from the gripper to the second wafer carrier, wherein the step of moving the second wafers is performed simultaneously with the step of moving the first wafers.

16. An apparatus, comprising:
a first wafer carrier support base over a carrying platform;
a second wafer carrier support base over the carrying platform and adjacent to the first wafer carrier support base;
a first placement bracket comprising a first bracket and a first placement platform supported on the first bracket and enclosed by the first wafer carrier support base, the first bracket initiating a first vertical motion of the first placement platform relative to the first wafer carrier support base;
a second placement bracket comprising a second bracket and a second placement platform supported on the second bracket and enclosed by the second wafer carrier support base, the second bracket initiating a second vertical motion of the second placement platform relative to the second wafer carrier support base;
a third bracket supporting the second wafer carrier support base, the third bracket initiating a third vertical motion of the second wafer carrier support base relative to the carrying platform; and
a gripper over the carrying platform, the gripper comprising:
a lifter extending along a first direction;
a horizontal movement guide rail liftable by the lifter and extending along a second direction perpendicular to the first direction; and
a lifting gripper platform movably coupled to the horizontal movement guide rail.

17. The apparatus of claim 16, further comprising:
a rotor between the first bracket and the first placement platform, the rotor initiating a rotation of the first placement platform relative to the first bracket.

18. The apparatus of claim 16, wherein the lifting gripper platform comprises:
a frame; and
a first clamping structure mounted on the frame, the first clamping structure comprising:
a pair of first clamping portions laterally spaced apart from each other;
a pair of first rotation limiting mechanisms on opposite ends of a first one of the pair of first clamping portions; and
a pair of second rotation limiting mechanisms on opposite ends of a second one of the pair of first clamping portions, the first and second rotation limiting mechanisms allowing rotations of the pair of first clamping portions to adjust a first lateral distance therebetween.

19. The apparatus of claim 18, wherein the lifting gripper platform further comprises:
a second clamping structure mounted on the frame and arranged with the first clamping structure along the second direction, the second clamping structure comprising:
a pair of second clamping portions laterally spaced apart from each other;
a pair of third rotation limiting mechanisms on opposite ends of a first one of the pair of second clamping portions; and
a pair of fourth rotation limiting mechanisms on opposite ends of a second one of the pair of second clamping portions, the third and fourth rotation limiting mechanisms allowing rotations of the pair of second clamping portions to adjust a second lateral distance therebetween.

20. The apparatus of claim 19, wherein the second lateral distance is greater than the first lateral distance.
